(19) United States
(12) Patent Application Publication
(10) Pub. No.: US 2010/0283539 A1
(43) Pub. Date: Nov. 11, 2010

(54) VOLTAGE DETECTION DEVICE

(75) Inventor: Koichi YANAGISAWA, Nagano (JP)

Correspondence Address: CANTOR COLBURN, LLP, 20 Church Street, 22nd Floor, Hartford, CT, 06103, US

(73) Assignee: HIOKI DENKI KABUSHIKI KAISHA, Nagano (JP)

(21) Appl. No.: 12/771,069

(22) Filed: Apr. 30, 2010

(30) Foreign Application Priority Data
Apr. 30, 2009 (JP) 2009-110304
May 13, 2009 (JP) 2009-116546
Jul. 21, 2009 (JP) 2009-169731
Aug. 3, 2009 (JP) 2009-180785
Mar. 25, 2010 (JP) 2010-069677
Mar. 25, 2010 (JP) 2010-069695
Mar. 25, 2010 (JP) 2010-069714

(51) Int. Cl. H03G 1/00

(52) U.S. Cl. 330/127

(57) ABSTRACT

A voltage detection device detects an objective AC voltage arising on a detection object. The voltage detection device includes; a detecting electrode placed so as to be capacitively coupled with the detection object; a reference signal output section for outputting a reference signal; a detecting section outputting a detection signal changing its amplitude in accordance with both current values of a detection object current flowing according to the objective AC voltage and a reference current flowing according to the reference signal; and a signal extracting section for extracting a signal component of the objective AC voltage from an amplified detection signal and outputting the signal component as an output signal, the amplified detection signal being obtained through controlling a gain for amplifying the detection signal so as to make a signal component of the reference signal included in the detection signal have a predetermined value.

### CROSS-REFERENCE TO RELATED APPLICATION

The present application claims priority from Japanese Patent Applications No. 2009-110304 filed on Apr. 30, 2009, No. 2009-116546 filed on May 13, 2009, No. 2009-169731 filed on Jul. 21, 2009, No. 2009-180785 filed on Aug. 3, 2009, No. 2010-69677 filed Mar. 25, 2010, No. 2010-69695 filed on Mar. 25, 2010, and No. 2010-69714 filed on Mar. 25, 2010, the contents of which are incorporated herein by reference.

### BACKGROUND OF THE INVENTION

1. Field of the Invention

The present invention relates to a contact-free type voltage detection device for detecting an objective AC voltage of a detection object without physical contact.

2. Description of Related Art

Known as this type of voltage detection device is a contact-free type voltage-measuring unit (hereinafter also called a “voltage detection device”) disclosed in Patent Document 1: Japanese Patent Publication No. 3158063 (Pages 4 through 6, and FIG. 3). The voltage detection device includes a detecting probe having a detecting electrode, which can cover a part of an insulator of an electric cable, and a shield electrode covering the detecting electrode, and an oscillator for outputting a signal of a predetermined frequency. By imposing a signal of the oscillator on the detecting electrode, the voltage detection device measures impedance between the detecting electrode and a conductor of the cable, and measures a current coming out of the detecting electrode due to the voltage imposed on the conductor by using a detecting resistor (a resistance value: R1) so as to enable determination of the voltage imposed on the conductor with reference to the current and the impedance.

Specifically to describe, in operation of the voltage detection device, a static capacitance between the shield electrode and the ground (hereinafter called a “first static capacitance” for explanation) is measured at first under conditions where the detecting probe is open and a signal from the oscillator is imposed on the detecting electrode through the detecting resistor. Since the resistance of the detecting resistor is so low enough as to be negligible in comparison with the reactance of the first static capacitance, the first static capacitance obtained through this measurement can be calculated by using the voltage signal output from the oscillator, the resistance of the detecting resistor, the angular frequency of the signal output from the oscillator, and an end-to-end voltage of the detecting resistor.

Secondly, another static capacitance (hereinafter called a “second static capacitance” for explanation) is measured under conditions where the detecting probe is closed to hold the cable and a signal from the oscillator is imposed on the detecting electrode through the detecting resistor. The second static capacitance measured through this step is a composite capacitance composed of the first static capacitance described above and another static capacitance between the detecting electrode and the cable (hereinafter called a “third static capacitance” for explanation). Since the resistance of the detecting resistor is so low enough as to be negligible in comparison with the reactance of the composite capacitance, the composite capacitance can be calculated by using the voltage signal output from the oscillator, the resistance of the detecting resistor, the angular frequency of the signal output from the oscillator, and an end-to-end voltage of the detecting resistor. Thus, subtracting the first static capacitance described above from the calculated second static capacitance results in the third static capacitance, which is namely the static capacitance between the detecting electrode and the conductor of the cable.

Subsequently, the end-to-end voltage of the detecting resistor resulting from the voltage imposed on the conductor is obtained under conditions where the detecting probe is closed to hold the cable and a signal from the oscillator is imposed on the detecting electrode through the detecting resistor. An impedance of the circuit passing through the detecting resistor, in view from the conductor, is a sum of the resistance value of the detecting resistor and the reactance of the third static capacitance. Since the resistance value of the detecting resistor is so small enough as to be negligible in comparison with the reactance of the third static capacitance, eventually the impedance is given by the reactance of the third static capacitance. Thus, the electric current flowing through the detecting resistor is defined as a value to be obtained through dividing the voltage imposed on the conductor by the reactance. Therefore, the end-to-end voltage of the detecting resistor is defined as a value to be obtained through multiplying the electric current flowing through the detecting resistor by the resistance value of the detecting resistor. In this case, the end-to-end voltage of the detecting resistor is expressed by using parameters of the angular frequency of the voltage imposed on the conductor, the third static capacitance between the detecting electrode and the cable, the voltage imposed on the conductor, and the resistance value of the detecting resistor. Thus, in operation of the voltage detection device, the voltage imposed on the conductor is calculated by using the end-to-end voltage of the detecting resistor, the angular frequency of the voltage imposed on the conductor, the third static capacitance between the detecting electrode and the cable, and the resistance value of the detecting resistor, and then the voltage is indicated on a display section.

### SUMMARY OF THE INVENTION

Unfortunately, the voltage detection device described above involves a problem as described below. That is to say, the voltage detection device requires independently calculating the static capacitance between the shield electrode and the ground (i.e., the first static capacitance described above) as well as the static capacitance between the detecting electrode and the conductor of the cable (i.e., the third static capacitance described above), and then operation of detecting the voltage imposed on the conductor requires great care and takes much time.

For solving the problem described above, it is an object of the present invention to provide a contact-free type voltage detection device that enables detecting the voltage of a detection object (the conductor of the cable in the example described above) without calculating the static capacitance between the detecting electrode and the detection object.

According to the present invention, there is provided a voltage detection device for detecting an objective AC voltage arising on a detection object, including: a detecting electrode placed so as to face the detection object and to be capacitively coupled with the detection object; a reference signal output section for outputting a reference signal; a detecting section connected to the detecting electrode and receiving the reference signal to output a detection signal changing its amplitude in accordance with both current values of a detection object current flowing according to the objective AC voltage and a reference current flowing according to the reference signal; and a signal extracting section for extracting a signal component of the objective AC voltage from an amplified detection signal and outputting the signal component as an output signal, the amplified detection signal being obtained through controlling a gain for amplifying the detection signal so as to make a signal component of the reference signal included in the detection signal have a predetermined value.

The signal extracting section may include; a control circuit for controlling the gain so as to cancel out the reference signal and a signal component of the reference signal included in the amplified detection signal each other by either addition or subtraction of the reference signal output from the reference signal output section and the amplified detection signal; and a circuit for outputting a signal as a signal component of the objective AC voltage, the signal being generated by canceling the signal component of the reference signal included in the amplified detection signal therefrom.

According to this configuration; the detecting section is connected to the detecting electrode being capacitively coupled with the detection object, and the detecting section receives the reference signal from the reference signal output section, and outputs the detection signal changing its amplitude in accordance with both the current values of the detection object current flowing according to the objective AC voltage of the detection object and the reference current flowing according to the reference signal. Then, the signal extracting section amplifies the detection signal with the predetermined gain and generates the amplified detection signal, and then the signal extracting section controls the gain so as to enable canceling out the reference signal and the signal component of the reference signal included in the amplified detection signal each other by either addition or subtraction of the reference signal output from the reference signal output section and the amplified detection signal, and extracts the signal component of the objective AC voltage from the amplified detection signal and outputs the signal component as the output signal.

In this case, the current due to the reference signal and the current due to the objective AC voltage flow through the current path including a coupling capacitance (static capacitance) between the detection object and the detecting electrode, and the detection signal is composed of the voltage components derived from both the currents (i.e., the signal component of the reference signal and the signal component of the objective AC voltage).

Therefore, even when the coupling capacitance between the detection object and the detecting electrode is unknown, the sensitivity on the detective AC voltage is controlled to be constant. In other words, the amplitude of the signal component of the objective AC voltage included in the output signal is so controlled as to have a level corresponding to the amplitude of the objective AC voltage. As a result, detection of the voltage component included in the output signal enables contact-free detection of the objective AC voltage by the voltage detection device without calculation of the coupling capacitance.

Alternatively, the signal extracting section may include a control circuit for controlling the gain so as to make the predetermined value coincide with a constant value specified beforehand.

According to such configuration; the detecting section is connected to the detecting electrode being capacitively coupled with the detection object, and the detecting section receives the reference signal from the reference signal output section, and outputs the detection signal changing its amplitude in accordance with both the current values of the detection object current flowing according to the objective AC voltage of the detection object and the reference current flowing according to the reference signal. Then, the signal extracting section amplifies the detection signal with the predetermined gain and generates the amplified detection signal, and then the signal extracting section controls the gain so as to make the signal component of the reference signal included in the amplified detection signal have a constant amplitude, and extracts the signal component of the objective AC voltage from the amplified detection signal and outputs the signal component as the output signal.

In this case, the current due to the reference signal and the current due to the objective AC voltage flow through the current path including a coupling capacitance (static capacitance) between the detection object and the detecting electrode, and the detection signal is composed the voltage components derived from both the currents (i.e., the signal component of the reference signal and the signal component of the objective AC voltage).

Then, in the voltage detection device, the signal extracting section controls the gain of the insulated detection signal so as to make the signal component of the reference signal included in the amplified detection signal have a constant amplitude, in order to generate the amplified detection signal. Therefore, even when the coupling capacitance between the detection object and the detecting electrode is unknown or regardless of the capacitance value of the coupling capacitance, the sensitivity on the signal component of the detective AC voltage included in the amplified detection signal is controlled to be constant. In other words, the amplitude of the signal component of the objective AC voltage included in the output signal is so controlled as to have a level corresponding to the amplitude of the objective AC voltage. Then, in accordance with the amplitude of the output signal including the signal component of the objective AC voltage, the objective AC voltage can be accurately detected. As a result, saving the effort of calculating the coupling capacitance (static capacitance) between the detection object and the detecting electrode or without calculation of coupling capacitance, the voltage detection device enables contact-free detection of the objective AC voltage.

The voltage detection device may further include a judging section for detecting a level of the signal component of the reference signal included in one of the detection signal and the amplified detection signal, and carrying out at least one of two judging operations; one judging operation judging the voltage detection to be in normal condition when the level detected is equal to or higher than a predetermined level, and the other judging operation judging the voltage detection to be in abnormal condition when the level detected is lower than the predetermined level.

When the detection electrode and the detection object capacitively couple each other while the voltage detection device is operating normally, the current component due to the reference signal output from the reference signal output section flows between the detection object and the detecting section. Then, the signal component due to the current component is always included in the detection signal, etc., and the amplified detection signal. Therefore, as an example, if a lower limit of the level of the signal component of the reference signal, i.e. the signal component due to the reference signal, included in the detection signal, etc., and the amplified detection signal under normally operating condition is calculated as the predetermined level beforehand, the judging section detects the level of the signal component of the reference signal included in one of the detection signal, etc., and the amplified detection signal, and then carries out at least one of the two judging operations; one judging operation judging the voltage detection to be in normal condition when the level detected is equal to or higher than the predetermined level, and the other judging operation judging the voltage detection to be in abnormal condition when the level detected is lower than the predetermined level. Then, according to the result of the judging operation, an operator can make a diagnosis or judgment on whether the corresponding voltage detection device is executing the voltage detection normally or not.

Furthermore, the operator can find whether the detected objective AC voltage is from operation in normal condition or abnormal condition so that the reliability of the detected objective AC voltage can be improved.

The voltage detection device may further include a power supply unit for driving the detecting section with a floating voltage using the reference signal coming from the reference signal output section as a reference voltage.

The signal extracting section may include; an amplifying circuit for creating the amplified detection signal by amplifying the detection signal, a synchronous detection circuit for detecting a detection signal showing the amplitude of the signal component of the reference signal included in one of the amplified detection signal and the output signal, through synchronous detection using the reference signal output from the reference signal output section, and a control circuit for controlling a gain of the amplifying circuit according to the detection signal.

Through synchronous detection, the signal component of the reference signal can be detected accurately, and therefore the detection signal can be detected with high accuracy. Thus, the amplitude of the signal component of the objective AC voltage included in the output signal can be controlled stably with high accuracy so that accuracy of detecting the objective AC voltage can be further improved.

For driving the detecting section with a floating voltage, the voltage detection device may further include an insulator section for handing over the detection signal from the detecting section to the signal extracting section under conditions where the detecting section and the signal extracting section are electrically insulated from each other.

If a guard electrode, for example, is used as a reference voltage section, the detecting section can operate under floating condition with the guard electrode accommodating the detecting electrode, the floating power supply, the detecting section, and the insulator section in it. As a result, CMRR (Common Mode Rejection Ratio) can be increased.

For driving the detecting section with a floating voltage, the power supply unit may include a first series power supply circuit for creating a first floating voltage as a certain positive voltage in comparison to the voltage of the reference signal, with reference to the positive voltage out of a positive voltage and a negative voltage supplied to the reference signal output section and the signal extracting section, and the power supply unit may supply the detecting section with each of the floating voltages.

The configuration described above results in avoidance of using expensive components such as a battery and a transformer so that production costs of the voltage detection device can substantially be reduced.

The first series power supply circuit may include; a first resistor connected to the positive voltage, a first Zener diode operating with a current supplied from the first resistor, and a first transistor having its collector terminal connected to the positive voltage, having its base terminal receiving a Zener voltage from the first Zener diode, and creating the first floating voltage at its emitter terminal; and the second series power supply circuit may include; a second resistor connected to the negative voltage, a second Zener diode operating with a current supplied from the second resistor, and a second transistor having its collector terminal connected to the negative voltage, having its base terminal receiving a Zener voltage from the second Zener diode, and creating the second floating voltage at its emitter terminal.

Being configured with a resistor, a Zener diode, and a transistor, each of the first and second series power supply circuits can be prepared simply and inexpensively with a less number of components.

For extracting the signal, in which the signal component of the reference signal has been canceled out, as the signal component of the objective AC voltage, the signal extracting section may include one of, an adding circuit for canceling out the reference signal output from the reference signal output section and the signal component of the reference signal by the addition, and then outputting the output signal, and a subtracting circuit for canceling out the reference signal output from the reference signal output section and the signal component of the reference signal by the subtraction, and then outputting the output signal.

According to the configuration described above, by using a circuit that can easily be configured with either an adding circuit or a subtracting circuit, the output signal can be output through canceling out the signal component of the reference signal and the reference signal each other. Therefore, with simplifying the configuration of the voltage detection device, the output signal can surely be output.

For extracting the signal component, in which at least the frequency component of the reference signal has been removed from the amplified detection signal, the signal extracting section may include a filter for extracting a signal component of the objective AC voltage from the amplified detection signal, and outputting the signal component.

Employing the filter for extracting the signal component of the objective AC voltage from the amplified detection signal, the voltage detection device can generate the output signal at low cost by using a simple configuration.

The voltage detection device may further include an amplitude modifying section for changing the amplitude of the reference signal output from the reference signal output section in order to control the gain of the detection signal in the signal extracting section, and outputting the signal with the changed amplitude to the signal extracting section.

According to the configuration described above; wherein a magnification k is defined by comparing the modified amplitude of the reference signal to the amplitude of the reference signal before the magnification, the objective AC voltage can be detected through multiplying the amplitude of the output signal including the signal component of the objective AC voltage by 1/k. Therefore, the detectable range of the objective AC voltage can be expanded by changing the magnification k.

The voltage detection device may further include a processing section for detecting the objective AC voltage based on the output signal. Such a configuration, for example, enables the processing section to detect the objective AC voltage at constant interval, and enables a display apparatus to show the detected objective AC voltage as a waveform so as to enhance the convenience of the operation.

In this case, the processing section may calculate a voltage value of the objective AC voltage based on the output signal. Thus, the objective AC voltage can accurately be detected or measured.

The reference signal output section may include; a rectangular waveform generation circuit for generating a rectangular waveform, and an integrating circuit for integrating the rectangular waveform and outputting the integration result as an integrated rectangular waveform; and the integrated rectangular waveform is output to the detecting section as the reference signal; and the rectangular waveform is output to the signal extracting section as the reference signal.

According to the configuration described above; configuring the rectangular waveform generation circuit simply by making use of a logic circuit simplifies an entire part of the reference signal output section, and makes the reference current, flowing according to the reference signal, the same as the rectangular waveform that is output from the reference signal output section to the signal extracting section. Thus, with the device configuration, specifically a configuration of an entire part of the reference signal output section, being simplified, the reference signal and the signal component of the reference signal included in the amplified detection signal can certainly be canceled off each other in the signal extracting section. As a result, the signal component of the objective AC voltage can be extracted for sure out of the amplified detection signal, and then output as the output signal.

Alternatively, the reference signal output section may include a pseudo noise generating circuit for generating a pseudo noise, and the pseudo noise is output to the detecting section and the signal extracting section as the reference signal.

Using a pseudo noise as the reference signal can make it harder for an external disturbance or noise to influence the operation.

An inter-line voltage detection device can be configured by using a plurality of voltage detection devices according to the present invention. Namely, such an inter-line voltage detection device includes: a plurality of voltage detection devices for detecting AC voltages arising on a plurality of electrical paths as a detection object; and a calculating section for calculating difference voltages of the AC voltages detected by the plurality of voltage detection devices in order to obtain inter-line voltages between the electrical paths; wherein the voltage detection device described above is used for materializing each of the plurality of voltage detection devices.

Even when coupling capacitances between the electrical paths as the detection object and the detecting electrodes facing to the electrical paths are unknown, contact-free detection of the inter-line voltages between the electrical paths can be carried out accurately without calculation of the coupling capacitances (static capacitances) between the electrical paths and the detecting electrodes.

### BRIEF DESCRIPTION OF THE DRAWINGS

Specific embodiments of the present invention will now be described, by way of example only, with reference to the accompanying drawings in which:

FIG. 1 is a block diagram of a voltage detection device in accordance with a first embodiment of the present invention;

FIG. 2 is a circuit diagram of a floating circuit section in the voltage detection device shown in FIG. 1;

FIG. 3 is a circuit diagram of an amplifying circuit in the voltage detection device shown in FIG. 1;

FIG. 4 is a block diagram of a voltage detection device in accordance with a second embodiment of the present invention;

FIG. 5 is a circuit diagram of a detecting section in the voltage detection device shown in FIG. 4;

FIG. 6 is a block diagram of a reference signal output section that is different from corresponding ones shown in FIG. 1 and FIG. 4, and that can replace the reference signal output section of the voltage detection device shown in FIG. 1 or FIG. 4;

FIG. 7 is a block diagram of another reference signal output section that can replace the reference signal output section of the voltage detection device in FIG. 1 or FIG. 4, and that is also different from the corresponding one shown in FIG. 6;

FIG. 8 is a block diagram of an inter-line voltage detection device using the voltage detection device shown in FIG. 1;

FIG. 9 is a block diagram of an inter-line voltage detection device using the voltage detection device shown in FIG. 4;

FIG. 10 is a block diagram of a floating circuit of a voltage detection device equipped with a power supply section that is different from a power supply section of the voltage detection device shown in FIG. 1 or FIG. 4;

FIG. 11 is a circuit diagram of the power supply section of the floating circuit section shown in FIG. 10;

FIG. 12 is a circuit diagram of a floating circuit section and a differential amplifier circuit of a configuration in which no insulator section is used;

FIG. 13 is a block diagram of a voltage detection device in accordance with a third embodiment of the present invention;

FIG. 14 is a block diagram of a voltage detection device in accordance with a fourth embodiment of the present invention;

FIG. 15 is a block diagram of a voltage detection device in accordance with a fifth embodiment of the present invention;

FIG. 16 is a block diagram of a voltage detection device in accordance with a sixth embodiment of the present invention;

FIG. 17 is a block diagram of a voltage detection device in accordance with a seventh embodiment of the present invention;

FIG. 18 is a frequency characteristic diagram of a voltage signal S4 output from a feedback control section in the voltage detection device shown in FIG. 17;

FIG. 19 is a frequency characteristic diagram of a reference signal Sr as a datum for extracting a signal in a signal extracting section in the voltage detection device shown in FIG. 17;

FIG. 20 is a frequency characteristic diagram of an insulated detection signal S2 output from a floating circuit section in the voltage detection device shown in FIG. 17;

FIG. 21 is a frequency characteristic diagram of an amplified detection signal S3 generated in an amplifying circuit in the voltage detection device shown in FIG. 17; and

FIG. 22 is a frequency characteristic diagram of an output signal So output from the signal extracting section in the voltage detection device shown in FIG. 17.

### DETAILED DESCRIPTION OF THE PREFERRED EMBODIMENTS

With reference to the accompanying drawings, embodiments of the voltage detection device and the inter-line voltage detection device are described below.

### First Embodiment

At first, with reference to the accompanying drawings, here is described a voltage detection device 101 of a first embodiment in accordance with the present invention.

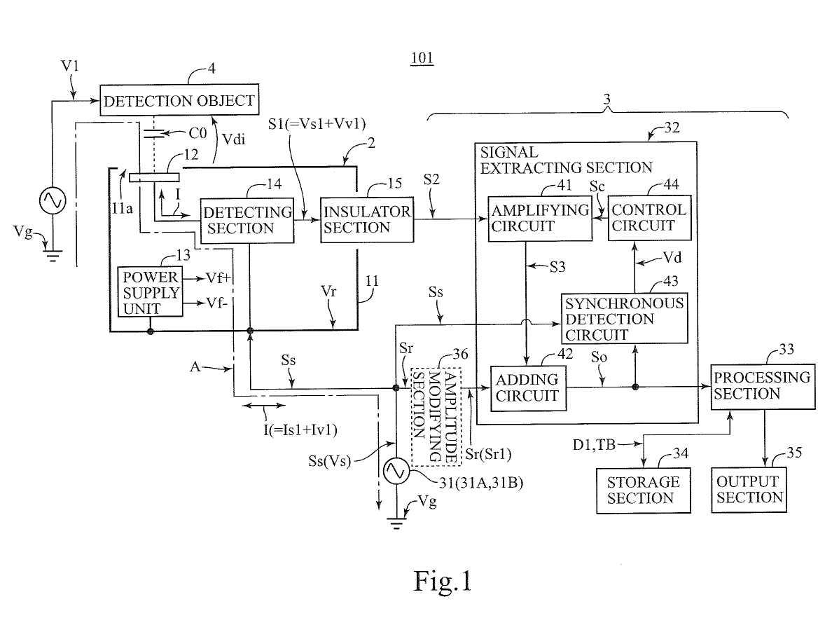

The voltage detection device 101 is a contact-free type voltage detection device comprising, as shown in FIG. 1, a floating circuit section 2 and a main circuit section 3.

The voltage detection device 101 is configured to be able to detect, by taking a ground electric potential Vg as a reference, an AC voltage V1 (an objective AC voltage) arising on a detection object 4 without physical contact.

As shown in FIG. 1, the floating circuit section 2 includes a guard electrode 11, a detecting electrode 12, a power supply unit 13, a detecting section 14, and an insulator section 15. The guard electrode 11, being constructed with a conductive material (e.g., a metal material) and configured as a reference voltage section in the floating circuit section 2, internally accommodates the detecting electrode 12, the detecting section 14, and the insulator section 15. As described later, the insulator section 15 has a function for outputting a signal, which is input through a primary side circuit of the insulator section 15, from a secondary side circuit of the insulator section 15, with the signal being electrically insulated from the primary side circuit. Therefore, the guard electrode 11 should cover at least the primary side circuit, and may cover the secondary side circuit as well. In this embodiment, an opening or aperture 11a for example is formed in the guard electrode 11. Being constructed as a flat plate for example, the detecting electrode 12 is located at a position facing the opening 11a inside the guard electrode 11, with being out of contact with the guard electrode 11. At the time of detecting the AC voltage V1, the detecting electrode 12 capacitively couples with the detection object 4 (through the intermediary of a static capacitance C0) as shown in FIG. 1.

The power supply unit 13 is so configured as to be a floating power supply for creating various floating voltages with referring a voltage Vr of the guard electrode 11 as a reference (0 volt). Then, the power supply unit 13 supplies each generated floating voltage as an operational voltage to each constituent element placed inside the guard electrode 11. In the present embodiment, as an example, the power supply unit 13 comprises a battery and a DC/DC converter (which are not shown in the drawing), wherein the DC/DC converter generates various floating voltages (for example, a first floating voltage Vf+ that is a positive voltage in comparison with the voltage Vr, and a second floating voltage Vf− having the same absolute value as the first floating voltage Vf+, and being a negative voltage in comparison with the voltage Vr, wherein the voltage Vr being 0 volt: hereinafter, these voltages are also called simply “floating voltage Vf+”, and “floating voltage Vf−”, respectively) as operational voltages by using a DC voltage output from the battery. Though it is not shown in the drawing, it may be configured that an AC voltage is supplied into the guard electrode 11 from the outside of the guard electrode 11 through a transformer instead of using the battery with an external power supply line being electrically insulated, and then a rectifying smoother section placed in the guard electrode 11 converts the AC voltage into a DC voltage to supply it to the DC/DC converter.

The detecting section 14 is connected to the detecting electrode 12 and receives a reference signal Ss, or is applied the reference signal Ss, from a reference signal output section 31 to output a detection signal S1 that changes its amplitude according to two current values, one is a detection object current Iv1 flowing in accordance with the AC voltage V1, which is a current signal component due to the AC voltage V1, and the other is a reference current Is1 flowing in accordance with the reference signal Ss, which is a current signal component due to the reference signal Ss. Concretely to describe, the detecting section 14 is supplied with the floating voltage Vf+ and the floating voltage Vf− that are a positive voltage and a negative voltage, respectively, in comparison with the voltage Vr of the guard electrode 11 to carry out its operation. Then, in accordance with a current signal I (a detection current) flowing with a current value according to an AC potential difference between the AC voltage V1 and the voltage Vr of the guard electrode 11, the detecting section 14 genarates and outputs the detection signal S1 that changes its amplitude according to the AC potential difference (V1−Vr). Under this situation, the reference signal Ss from the reference signal output section 31, to be described later, is output to (applied on) the guard electrode 11. In this configuration, the voltage Vr becomes equal to a voltage Vs of the reference signal Ss. Thus, the current signal I described above comprises the reference current Is1 due to the reference signal Ss and the detection object current Iv1 due to the AC voltage V1, and meanwhile in the same manner, the detection signal S1 derived from the current signal I comprises a voltage signal component Vs1 (hereinafter called a “reference voltage component”) derived from the reference current Is1 and another voltage signal component Vv1 (hereinafter called a “detection object voltage component”) derived from the detection object current Iv1. Since the detecting section 14 operates according to the voltage of the guard electrode 11, which changes together with the voltage Vs of the reference signal Ss, in order to generate the detection signal S1, the reference voltage component Vs1 included in the detection signal S1 is an anti-phase signal in comparison to the voltage Vs of the reference signal Ss.

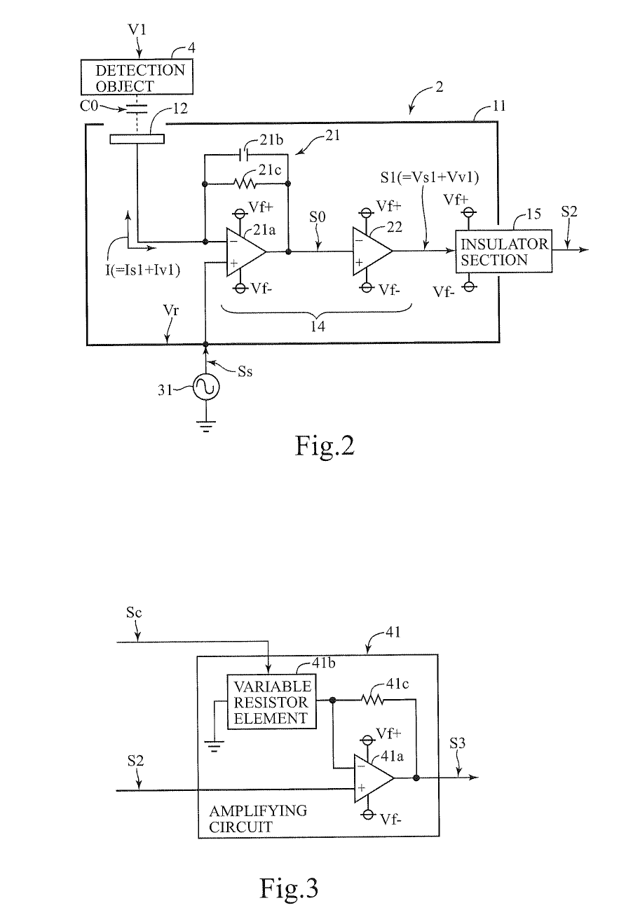

In the present embodiment, as an example, the detecting section 14 includes an integrating circuit 21 and an amplifying circuit 22, as shown in FIG. 2. The integrating circuit 21 includes an operational amplifier 21a with its non-inverting input terminal connected to the guard electrode 11 and its inverting terminal connected to the detecting electrode 12, a condenser 21b connected between the inverting input terminal of the operational amplifier 21a and the output terminal, and a resistor 21c connected in parallel with the condenser 21b. In this case, capacitance of the condenser 21b is about 0.01 microfarad for example, and meanwhile the resistor 21c has a relatively high resistance value of about 1 mega-ohm for example. Thus, in the integrating circuit 21, the current signal I principally flows through the condenser 21b so that integrating operation is carried out at the same time as current-voltage converting operation to generate voltage signal S0 that changes its voltage value in proportion to the AC potential difference between the AC voltage V1 of the detection object 4 and the voltage Vr of the guard electrode 11 (V1−Vr). Incidentally, in the integrating circuit 21, having only the condenser 21b significantly reduces a feedback amount around a DC current so as to make the gain extremely large, and consequently the operational amplifier 21a may be saturated with an offset by the bias current. Therefore, in order to prevent a decrease in dynamic range by the saturation, the resistor 21c is placed. The amplifying circuit 22 voltage-amplifies the voltage signal S0 with a predetermined gain, and outputs the amplified signal as the detection signal S1. Though it is not shown in the drawing, the integrating circuit 21 may be configured for example with two circuits as well, one is a current-voltage converting circuit for converting the current signal I into a voltage signal and then the other is an integrating circuit that integrates the voltage signal for outputting the integrated signal as the detection signal S1.

The insulator section 15 receives the detection signal S1, and then outputs a signal as an insulated detection signal S2 electrically insulated from the detection signal S1. Specifically, the insulator section 15 is composed of for example an optical insulating element (for example, a photo-coupler in the present embodiment). Then, the detection signal S1 is input into a light-emitting diode (not shown) being as the primary side circuit, and the signal is output as the insulated detection signal S2, from a photo transistor being as the secondary side circuit. In other words, the insulator section 15 outputs a signal, which is in the same phase as the detection signal S1 and changes its amplitude in proportion to the amplitude of the detection signal S1, as the insulated detection signal S2. The insulator section 15 may also be configured with an optical MOS-FET (Field-Effect Transistor) instead of the photo-coupler, wherein the optical MOS-FET includes a light-emitting diode as a primary side circuit, and a couple of FETs as a secondary side circuit. In this case, the primary side circuit of the insulator section 15 carries out its operation, being supplied with the floating voltages Vf+ and Vf−. When the detection signal S1 is an AC signal having a high frequency, the insulator section 15 may also be configured with a transformer.

As shown in FIG. 1, the main circuit section 3 includes the reference signal output section 31, a signal extracting section 32, a processing section 33, a storage section 34, and an output section 35. In this case, the reference signal output section 31 generates the reference signal Ss in which the voltage Vs changes at predetermined cycles with reference to the ground electric potential Vg and the amplitude is constant (i.e., an AC signal with a constant frequency and a constant amplitude, for example, a sine-wave signal), and then the reference signal output section 31 outputs the signal to the guard electrode 11. Thus, the guard electrode 11 has its voltage Vr set with the voltage Vs of the reference signal Ss. In other words, the voltage Vr of the guard electrode 11 changes at predetermined cycles coinciding with the voltage Vs of the reference signal Ss. The reference signal output section 31 directly outputs the reference signal Ss to the guard electrode 11 in the present embodiment. Since the reference signal Ss is an AC signal, the reference signal output section 31 can be configured to output the reference signal Ss through a condenser to the guard electrode 11. Such an embodiment is not shown in the drawing. The reference signal output section 31 also outputs the reference signal Ss to the signal extracting section 32. Incidentally, an amplitude modifying section 36 indicated with a surrounding broken line in the drawing is not included in the main circuit section 3 in the present embodiment. Therefore, the reference signal Ss output from the reference signal output section 31 is directly input into the signal extracting section 32. In the present embodiment, as an example, the reference signal Ss has its frequency set higher than that of the AC voltage V1 of the detection object 4. However, in this case, the reference signal Ss may have its frequency set lower than that of the AC voltage V1 of the detection object 4.

The signal extracting section 32 comprises an amplifying circuit 41, an adding circuit 42, a synchronous detection circuit 43, and a control circuit 44 as an example for generating the amplified detection signal S3 by amplifying the insulated detection signal S2 with a predetermined gain, controlling a gain for amplifying the insulated detection signal S2 such that a signal component of the reference signal Ss included in the amplified detection signal S3 and the reference signal Ss itself can be cancelled by addition or subtraction of the amplified detection signal S3 and the reference signal Ss (by addition, in the present embodiment), and extracting or generating a signal component of the AC voltage V1 from the amplified detection signal S3 to output it as an output signal So. In this case, the signal component of the reference signal Ss included in the amplified detection signal S3 is a signal component due to the reference voltage component Vs1 included in the detection signal S1 by outputting (applying) the reference signal Ss to (on) the guard electrode 11, namely, a signal component having the same frequency as the reference signal Ss included in the amplified detection signal S3.

Specifically, the amplifying circuit 41 receives the insulated detection signal S2 and amplifies the insulated detection signal S2 with a gain (the gain may be greater or smaller than or equal to 1) set by a level (a DC voltage level) of a control signal Sc (specifically, a control voltage) output from the control circuit 44 to generate the amplified detection signal S3, and then outputs it. As an example, the amplifying circuit 41 comprises an operational amplifier 41a, a variable resistor element 41b (for example, a J-FET (Junction Field-Effect Transistor) in the present embodiment) placed between an inverting terminal of the operational amplifier 41a and a ground electric potential, and a resistor 41c placed between the inverting terminal of the operational amplifier 41a and an output terminal as shown in FIG. 3. The amplifying circuit 41 is configured on the whole as a non-inverting amplifying circuit. In this configuration, the variable resistor element 41b changes its resistance value in accordance with a level of the control signal Sc entered. Therefore, the amplifying circuit 41 changes its gain in accordance with the level of the control signal Sc entered, and amplifies the insulated detection signal S2 with the gain, and then outputs it as the amplified detection signal S3. The variable resistor element simply requires being an element that changes its resistance value in accordance with a voltage input externally, and may be configured by using any element or circuit other than a J-FET. In the present embodiment, as an example, the variable resistor element 41b is so configured as to decrease its resistance value when the level of the control signal Sc entered increases, and meanwhile to increase its resistance value when the level of the control signal Sc entered decreases. According to this configuration, the gain of the amplifying circuit 41 increases when the level of the control signal Sc increases, whereas it decreases when the level of the control signal Sc decreases.

The adding circuit 42 receives the voltage Vr as a reference signal Sr, the voltage Vr arising at the guard electrode 11 (in the present embodiment, only the reference signal Ss is imposed on the guard electrode 11, and therefore the reference signal Ss works as the reference signal Sr). Then, receiving the amplified detection signal S3, the adding circuit 42 adds both the signals S3 and Sr, and outputs the addition signal obtained through the add operation as the output signal So. In this case, as described above, the detection signal S1 comprises the reference voltage component Vs1 having an anti-phase in comparison to the reference signal Ss, and the detection object voltage component Vv1 having the same phase as the AC voltage V1. Thus, the insulated detection signal S2 generated on the basis of the detection signal S1 and also the amplified detection signal S3 generated by amplification of the insulated detection signal S2 comprise a signal component having an anti-phase in comparison to the reference signal Ss and another signal component having the same phase as the AC voltage V1. Accordingly, through adding both the signals S3 and Sr, the adding circuit 42 carries out a process of canceling the signal component having an anti-phase (hereinafter, also called the “anti-phase signal component”) in comparison to the reference signal Ss included in the amplified detection signal S3 by using the reference signal Sr (the reference signal Ss in the present embodiment). In other words, the adding circuit 42 functions as a canceling circuit. In this case, when the amplitude of the anti-phase signal component included in the amplified detection signal S3 is equal to the amplitude of the reference signal Sr, a signal component having the same frequency as the reference signal Ss included in the output signal So is completely cancelled (deleted) and removed. In the meantime, when the amplitude of the anti-phase signal component included in the amplified detection signal S3 is different from the amplitude of the reference signal Sr, the signal component having the same frequency as the reference signal Ss remains in the output signal So. Thus, when the amplitude of the anti-phase signal component included in the amplified detection signal S3 is greater than the amplitude of the reference signal Sr, the signal component has an anti-phase in comparison to the reference signal Ss. Contrarily, when the amplitude of the anti-phase signal component included in the amplified detection signal S3 is smaller than the amplitude of the reference signal Sr, the signal component has the same phase as the reference signal Ss.

The synchronous detection circuit 43 receives the output signal So and the reference signal Ss, generates a detection signal Vd through synchronous-detection of the output signal So with the reference signal Ss, and outputs the detection signal. Specifically, the synchronous detection circuit 43 generates and outputs the detection signal Vd through synchronous-detection, wherein absolute values of the voltage of the detection signal Vd change in accordance with the change in the amplitude of the signal component of the reference signal Ss included in the output signal So (Concretely to describe, the signal component having the same frequency as the reference signal Ss), and polarities of the detection signal Vd are different from each other in the following two cases, depending on whether the phase of the signal component in the reference signal Ss included in the output signal So coincides with the phase of the reference signal Ss (in the same phase) or the above phases have a 180-deg difference between them (in an anti-phase). In the present embodiment, as an example, when the predetermined signal component included in the output signal So and the reference signal Ss are in the same phase, a positive polarity (a positive voltage) is given, whereas the above two are in an anti-phase, a negative polarity (a negative voltage) is given, and the synchronous detection circuit 43 generates and outputs the detection signal Vd provided with the polarity as described above.

The control circuit 44 generates the control signal Sc, which changes its voltage, according to the polarity of the detection signal Vd entered, and outputs the signal to the amplifying circuit 41. In the present embodiment, as an example, the control circuit 44 increases the voltage level of the control signal Sc when the detection signal Vd has a positive polarity, whereas it decreases the voltage level of the control signal Sc when the detection signal Vd has a negative polarity. According to the configuration described above, feedback control for the gain (amplification ratio) of the amplifying circuit 41 is carried out in the signal extracting section 32 by the synchronous detection circuit 43 and the control circuit 44, wherein the control circuit 44 controls the gain of the amplifying circuit 41 according to the detection signal Vd so as to make the anti-phase signal component (the signal component having the same frequency as the reference signal Ss) included in the amplified detection signal S3 have a constant amplitude (so as to have the same amplitude as that of the reference signal Ss input as the reference signal Sr into the adding circuit 42 in the present embodiment). As a result, the amplitude of the anti-phase signal component included in the amplified detection signal S3 coincides with the amplitude of the reference signal Sr (the reference signal Ss in the present embodiment) input into the adding circuit 42. Therefore, the adding circuit 42 adds the amplified detection signal S3 and the reference signal Sr, cancels the anti-phase signal component included in the amplified detection signal S3 by using the reference signal Ss, and then generates and outputs the output signal So including the voltage component (the signal component having the same frequency as the AC voltage V1) derived from the detection object current Iv1 due to the AC voltage V1 of the detection object 4.

In this case, according to the static capacitance C0 formed between the detection object 4 and the detecting electrode 12, the reference current Is1 and the detection object current Iv1, included in the current signal I, fluctuate in the same ratio, and then the reference voltage component Vs1 and the detection object voltage component Vv1, included in the detection signal S1, also fluctuate in the same ratio. Consequently, the anti-phase signal component (the signal component having the same frequency as the reference signal Ss) and the signal component having the same frequency as the AC voltage V1, comprising of the amplified detection signal S3, also fluctuate in the same ratio. Through the feedback control in the signal extracting section 32 as described above, the amplified detection signal S3 is generated by the amplifying circuit 41 in such a way that the amplitude of the anti-phase signal component (the signal component having the same frequency as the reference signal Ss) included in the signal S3 coincides with the amplitude of the reference signal Sr (the reference signal Ss in the present embodiment). Thus, in the voltage detection device 101 with the configuration of the present embodiment, the voltage component derived from the detection object current Iv1 included in the output signal So becomes to have an amplitude corresponding to, theoretically coincident with, the amplitude of the AC voltage V1 arising on a detection object 4, regardless of the static capacitance C0.

The processing section 33 comprisies an A/D converter and a CPU (both the two are not shown in the drawing) to execute a storing operation, in which a voltage waveform (level) of the output signal So is sampled by using a sampling clock with a predetermined frequency, and converted into digital data D1, and then the data is stored in the storage section 34, a voltage calculating operation for calculating the AC voltage V1 based on the digital data D1, and an output operation for outputting the AC voltage V1 calculated. The storage section 34 comprises a ROM and a RAM to store in advance a voltage calculation table TB to be used through the voltage calculating operation in the processing section 33. An outline of procedures of creating the voltage calculation table TB is described below. In this case as an example, the voltage calculation table TB is created through obtaining digital data D1 with changing the amplitude of the AC voltage V1 generated at the detection object 4 by a predetermined voltage step under a condition where the feedback control is carried out by the synchronous detection circuit 43 and the control circuit 44 with the reference signal Ss of a known voltage Vs (constant) being output to the guard electrode 11, associating the obtained digital data D1 with the voltage value of the AC voltage V1 changed by the predetermined voltage step, and storing the digital data D1 together with the voltage value of the AC voltage V1. According to this configuration, the processing section 33 can calculate the AC voltage V1 of the detection object 4 through obtaining the voltage value of the AC voltage V1 corresponding to the obtained digital data D1 by referring to the voltage calculation table TB. The output section 35 in the present embodiment, as an example, is configured with a display apparatus to show a waveform of the AC voltage V1 and calculated voltage parameters (such as amplitudes and RMS values) according to the output operation by the processing section 33.

Described below is a detecting operation for the AC voltage V1 of the detection object 4 by the voltage detection device 101.

The floating circuit section 2 (or an entire part of the voltage detection device 101) is placed in the vicinity of the detection object 4 in order for the detecting electrode 12 to face the detection object 4 without physical contact. Thus, as shown in FIG. 1, the static capacitance C0 is formed between the detecting electrode 12 and the detection object 4. Under this condition, the static capacitance C0 changes in inverse proportion to a distance between the detecting electrode 12 and the detection object 4. However, after the floating circuit section 2 is once placed, the capacitance becomes constant (without any change) as far as the temperature and other environment factors are constant. Then, since the static capacitance C0 is very small in general (for example, about several picofarads to tens of picofarads), an impedance existing between the detecting electrode 12 and the detection object 4 becomes great enough (several meg-ohms) even though the frequency of the AC voltage V1 is about several hundreds Hz. Accordingly, in the voltage detection device 101, an inexpensive device with a low withstanding input voltage may be used as the operational amplifier 21a included in the detecting section 14, even when the AC voltage V1 of the detection object 4 and the voltage Vr of the guard electrode 11 are widely different from each other (i.e., when the potential difference Vdi is large). Then, even in this arrangement described above, destruction of the operational amplifier 21a due to the potential difference Vdi can be avoided.

Since the detecting electrode 12 and the detection object 4 are alternating-current-wise connected through the static capacitance C0, there is formed a current path A (a route indicated with a dashed line in FIG. 1), starting from the ground electric potential Vg, through the detection object 4, the detecting electrode 12, the detecting section 14, the guard electrode 11, and the reference signal output section 31, down to the ground electric potential Vg. Through the current path A, there flows the current signal I comprising the reference current Is1 due to the voltage Vs of the reference signal Ss as well as the detection object current Iv1 due to the AC voltage V1 of the detection object 4.

Accordingly, as shown in FIGS. 1 and 2, the integrating circuit 21 of the detecting section 14 in the floating circuit section 2 integrates the current signal I to generate the voltage signal S0, and then the amplifying circuit 22 amplifies the voltage signal S0 to output it as the detection signal S1. The insulator section 15 receives the detection signal S1 and then outputs the insulated detection signal S2 electrically insulated from the detection signal S1.

As shown in FIG. 1, in the signal extracting section 32 of the main circuit section 3, the amplifying circuit 41 receives the insulated detection signal S2, and also amplifies the insulated detection signal S2 with the gain set by the voltage level of the control signal Sc output from the control circuit 44 to output the amplified detection signal S3. The adding circuit 42 receives the amplified detection signal S3 and the reference signal Sr, and then carries out an add operation of adding both the signals S3 and Sr to output the add result as the output signal So. In this case, as described above, feedback control for the gain (amplification ratio) of the amplifying circuit 41 is carried out by the synchronous detection circuit 43 and the control circuit 44 such that the amplitude of the anti-phase signal component (the signal component having the same frequency as the reference signal Ss) comprised in the amplified detection signal S3 coming from the amplifying circuit 41 coincides with the amplitude of the reference signal Sr (the reference signal Ss in the present embodiment). Therefore, through the add operation by the adding circuit 42, the anti-phase signal component included in the amplified detection signal S3 is canceled out with the reference signal Sr, in other words, the anti-phase signal component comprised in the amplified detection signal S3 is removed, and then the output signal So is obtained with comprising the voltage component (the signal component having the same frequency as the AC voltage V1) derived from the detection object current Iv1 due to the AC voltage V1 of the detection object 4.

The processing section 33 executes the storing operation to receive the output signal So, convert it into the digital data D1 and then store the data into the storage section 34. Subsequently, the processing section 33 executes the voltage calculating operation, in which the processing section 33 reads out the digital data D1 stored in the storage section 34 and retrieves the AC voltage V1 corresponding to the digital data D1 read out by referring to the voltage calculation table TB. Furthermore, the processing section 33 calculates, for example, amplitudes, RMS values, and other data of the AC voltage V1 by using the AC voltage V1 retrieved, and then stores the calculated data into the storage section 34. Finally, the processing section 33 executes the output operation to show the RMS values, amplitudes, and other data of the AC voltage V1, which the storage section 34 stores, on the output section 35 including the display device. Thus, the voltage detection device 101 completes detection of the AC voltage V1 of the detection object 4. For the output operation, it may be configured alternatively that the processing section 33 shows the voltage waveform of the AC voltage V1 in the output section 35 by using the AC voltage V1 obtained.

In the embodiment described above, the reference signal output section 31 outputs the reference signal Ss to the guard electrode 11. The detecting section 14, being supplied with the floating voltage Vf+ and the floating voltage Vf− for its operation, outputs the detection signal S1 that changes its amplitude according to the AC potential difference (V1−Vr), in accordance with a current signal I flowing between the detection object 4 and the guard electrode 11 through the detecting electrode 12 with a current value according to an AC potential difference between the AC voltage V1 and the voltage Vr of the guard electrode 11 (V1−Vr). The insulator section 15 receives the detection signal S1 and then outputs a signal as the insulated detection signal S2. The signal extracting section 32 controls the amplitude of the insulated detection signal S2 in such a way that the amplitude of the signal component, having the same frequency as the reference signal Ss included in the insulated detection signal S2, becomes equal to a predetermined amplitude (an amplitude that enables canceling a signal component having the same frequency as the reference signal Ss included in the amplified detection signal S3 by addition or subtraction with the reference signal Ss) or, in other words, the amplitude of the signal component becomes constant, and the signal extracting section 32 generates the amplified detection signal S3. Then, the signal extracting section 32 removes the signal component having the same frequency as the reference signal Ss included in the amplified detection signal S3 by addition or subtraction of the amplified detection signal S3 having its amplitude controlled as described above and the reference signal Ss output from the reference signal output section 31, and outputs the signal as the output signal So. The processing section 33 calculates the AC voltage V1 according to the level of the output signal So including the voltage component arising on the basis of the detection object current Iv1 (the current component due to the AC voltage V1 of the detection object 4).

Therefore, according to the present embodiment, the signal extracting section 32 controls the amplitude of the amplified detection signal S3 in order for the signal component having the same frequency as the reference signal Ss to have its constant amplitude, and removes the signal component having the same frequency as the reference signal Ss included in the amplified detection signal S3 by addition or subtraction of the amplified detection signal S3 and the reference signal Ss, and then outputs the signal as the output signal So. Then, even when a coupling capacitance between the detection object 4 and the detecting electrode 12 (the static capacitance C0) is unknown, (regardless of the value of the static capacitance C0) the sensitivity on the AC voltage V1 is controlled to be constant. In other words, the amplitude of the voltage component derived from the detection object current Iv1 included in the output signal So is so controlled as to have a level corresponding to the amplitude of the AC voltage V1. As a result, detection of the voltage component included in the output signal So enables contact-free detection of the AC voltage V1 without calculation of the static capacitance C0.

Furthermore, in the signal extracting section 32 of the present embodiment, the synchronous detection circuit 43 detects the detection signal Vd showing the amplitude of the signal component on the reference signal Ss included in the amplified detection signal S3 or the output signal So through synchronous detection using the reference signal Ss, and the control circuit 44 controls the gain of the amplifying circuit 41 according to the detection signal Vd. Therefore, the voltage detection device 101 enables accurate detection of the signal component of the reference signal Ss through synchronous detection. As a result, the signal component of the reference signal Ss included in the amplified detection signal S3 can be canceled with high accuracy, and then the signal component of the reference signal Ss included in the output signal So can be significantly reduced so that accuracy of detecting the AC voltage V1 can be further improved.

In the present embodiment, the signal extracting section 32 comprises the adding circuit 42, which carries out the process of cancelling the signal component having an anti-phase (the anti-phase signal component) in comparison to the reference signal Ss included in the amplified detection signal S3 by using the reference signal Sr (the reference signal Ss in the present embodiment), as a canceling circuit, and then the control circuit 44 controls the gain of the amplifying circuit 41 to enable canceling the anti-phase signal component (the signal component of the reference signal Ss) included in the amplified detection signal S3 input into the adding circuit 42 by using the reference signal Sr. Therefore, according to the voltage detection device 101, since the canceling circuit can be configured with a simple circuit such as the adding circuit, the output signal So can be generated securely with simplifying the device configuration.

According to the present embodiment, there is provided the processing section 33 for detecting the AC voltage V1 according to the output signal So so that it can make the processing section 33 detect the AC voltage V1 at constant intervals, store the detected AC voltage V1 in the storage section 34, and display the voltage waveform of the AC voltage V1 on the output section 35 according to the AC voltage V1 stored in the storage section 34.

According to the present embodiment, the processing section 33 calculates the AC voltage V1 according to the output signal So so that the AC voltage V1 can be detected (measured).

In the embodiment described above, making use of the relationship of the signal component of the reference signal Ss included in the amplified detection signal S3 having an anti-phase in comparison to the reference signal Sr (the reference signal Ss in the present embodiment), the adding circuit 42 as the canceling circuit cancels out the signal component of the reference signal Ss included in the amplified detection signal S3 and the reference signal Ss each other. Alternatively, in the detecting section 14, the insulator section 15, and the amplifying circuit 41, phases of the detection signal S1, the insulated detection signal S2, and the amplified detection signal S3 can be reversed. The reference signal Sr can be output to the canceling circuit with reversed. In such a configuration, since the signal component of the reference signal Ss included in the amplified detection signal S3 may have the same phase as the reference signal Ss, a subtracting circuit may be used as the canceling circuit for canceling out the signal component of the reference signal Ss included in the amplified detection signal S3 and the reference signal Ss each other.

According to the configuration in the embodiment described above, the reference signal Ss as the reference signal Sr is directly input into the canceling circuit (the adding circuit 42 in the embodiment described above). Alternatively, as indicated with a surrounding broken line in FIG. 1, the amplitude modifying section 36 may be placed between the reference signal output section 31 and the adding circuit 42 to multiply the amplitude of the reference signal Ss output from the reference signal output section 31 by k for change (wherein k is a positive real number) in the amplitude modifying section 36 and output the multiplied amplitude to the adding circuit 42 as a reference signal Sr1. The amplitude modifying section 36 can simply be configured, for example, with an attenuator configured by such as a voltage dividing resistor. The amplitude modifying section 36 may also be configured with an amplifier that amplifies the signal by a predetermined gain (k times) to make the amplitude of the reference signal Sr1 greater than the amplitude of the voltage signal Sr. In such a configuration, feedback control is carried out in the signal extracting section 32 to make the amplitude of the signal component of the reference signal Ss included in the amplified detection signal S3 and the amplitude of the reference signal Ss (the amplitude of the reference signal Sr1) magnified by k coincide with each other. In this case, when the signal component of the reference signal Ss included in the amplified detection signal S3 and the reference signal Sr1 magnified by k are canceled out each other in the adding circuit 42, the amplitude of the voltage component derived from the detection object current Iv1 due to the AC voltage V1 included in the output signal So is also detected being multiplied by k. Therefore, the AC voltage V1 can be detected by multiplying the voltage component according to the detected detection object current Iv1 by 1/k.

According to this configuration, the detectable (measurable) range of the AC voltage V1 can be expanded by changing the magnification k at the amplitude modifying section 36. For example, even when there exists a restriction of the input level of the output signal So at the processing section 33 (in the configuration including an A/D converter as described above, the input level of the output signal So is restricted according to the input rating of the A/D converter), setting the magnification k with a value 1/10 enables detection (measure) of the AC voltage V1 up to a higher voltage range, in comparison with a case where the magnification is set with a value “1” (Namely, the reference signal Ss is directly input into the adding circuit 42 as the reference signal Sr), while satisfying requirements for the input level of the output signal So.

In the present embodiment described above, there is accommodated the detecting electrode 12, the power supply unit 13, the detecting section 14, and the insulator section 15 within the guard electrode 11 so that the floating circuit section 2 is configured separately from the main circuit section 3 to increase CMRR (Common Mode Rejection Ratio) and to enable detection of the AC voltage V1 in a higher range. If it is not required to operate the detecting section 14 under floating condition (For example, when the AC voltage V1 is relatively low, or no high CMRR is requested), another configuration using neither the guard electrode 11, the power supply unit 13, nor the insulator section 15 may also be employed. Such a different embodiment is described below.

### Second Embodiment

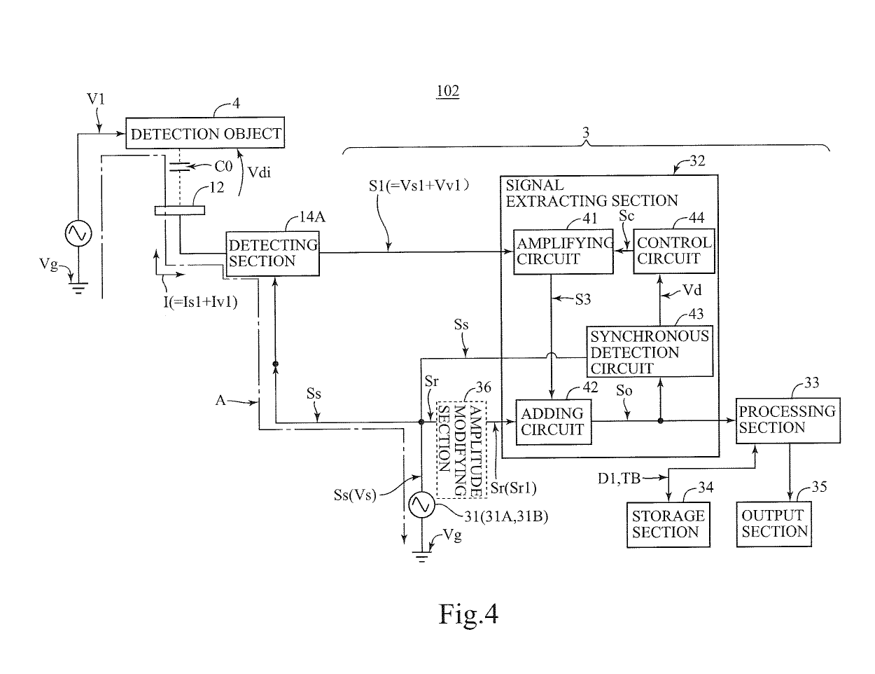

A voltage detection device 102 of a second embodiment in accordance with the present invention includes a detection electrode 12 and a detecting section 14A instead of the floating circuit section 2 of the voltage detection device 101, as shown in FIG. 4. Namely, the voltage detection device 102 comprises the detection electrode 12, the detecting section 14A and the main circuit section 3. The voltage detection device 102 is configured to be able to detect the AC voltage V1 arising on the detection object without physical contact. With respect to the detection electrode 12 and the main circuit section 3, the same configuration as that of the voltage detection device 101 is applied. Then, these components are provided with the same reference numerals, and any redundant explanation is omitted. Explanation is mainly given regarding the detecting section 14A that is placed differently from the voltage detection device 101.

The detecting section 14A is supplied with voltages for operation (i.e., a positive voltage Vcc+ and a negative voltage Vcc− generated on the basis of the ground electric potential Vg) from a power supply unit that is not shown in the figure, as other constituent elements of the main circuit section 3 (such as the reference signal output section 31, the signal extracting section 32, and the processing section 33) are. The detecting section 14A is connected to the detecting electrode 12 as shown in FIG. 4 and receives a reference signal Ss (while the reference signal Ss being imposed) so that the detecting section 14A detects a current signal I (=Iv1+Is1) including the detection object current Iv1, flowing between the detecting electrode 12 and the detection object 4 due to the presence of the AC voltage V1, and the reference current Is1 flowing between the detecting electrode 12 and the detection object 4 due to the input of the voltage Vs of the reference signal Ss, and then outputs the detection signal S1 that changes its amplitude according to a current value of the current signal I. The current signal I changes its amplitude according to the AC potential difference between the AC voltage V1 and the voltage Vr (=the voltage Vs) of the guard electrode 11 (V1−Vr). That is to say, the current signal I can be deemed to be a current signal of a current flowing in accordance with the potential difference (V1−Vr).

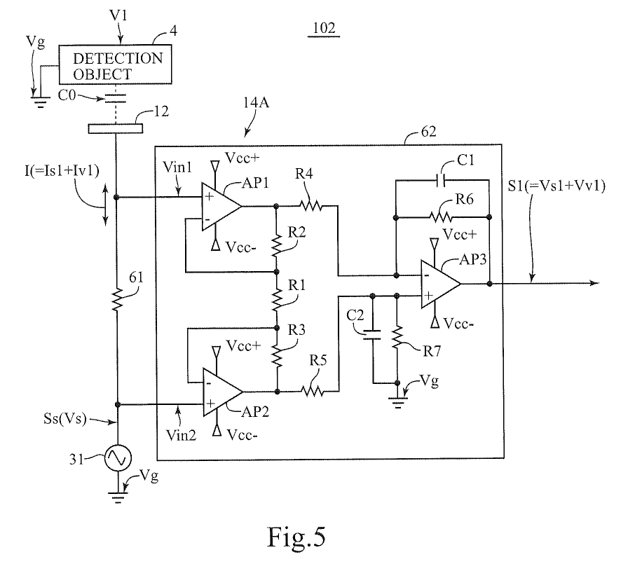

In the present embodiment, the detecting section 14A includes a detection resistor 61 and a differential amplifying section 62, as shown in FIG. 5 as an example. The detection resistor 61 is connected to the detecting electrode 12 at one end, and connected to the reference signal output section 31 at the other end. The differential amplifying section 62 is configured with a publicly known instrumentation amplifier including 3 operational amplifiers AP1 through AP3 and 7 resistors R1 through R7. In the differential amplifying section 62, condensers C1 and C2 are connected in parallel with the resistors R6 and R7, respectively, to provide an output stage including the operational amplifier AP3 with an integration function. Among the resistors R1 through R7 in the differential amplifying section 62, two resistors located at counterpart positions with each other are mutually balanced out (i.e., the resistors R2 and R3 are set with the same resistance value, so are the resistors R4 and R5, and also are the resistors R6 and R7). The condensers C1 and C2 are also mutually balanced out (i.e., the condensers C1 and C2 are set with the same capacitance value). In the differential amplifying section 62, a non-inverting input terminal of the operational amplifier AP1 functioning as one input terminal of the differential amplifying section 62 is connected at one side of the detection resistor 61, and a non-inverting input terminal of the operational amplifier AP2 functioning as the other one input terminal of the differential amplifying section 62 is connected to the reference signal output section 31. In the differential amplifying section 62, by using voltage values Vin1 and Vin2 of voltages input into input terminals independently, the detection signal S1 can be expressed with the following formula.

S1=(Vin2−Vin1)×(1+2×R2/R1)×R6/R4

In this instance, (Vin2−Vin1) of the formula of S1 described above expresses a voltage that arises between both ends of the detection resistor 61 when a current signal I (=Iv1+Is1) flows. Therefore, the detecting section 14A outputs the detection signal S1 that changes its amplitude according to a current value of the current signal I (=Iv1+Is1), as described above.

In the main circuit section 3, the signal extracting section 32 amplifies the detection signal S1 with a predetermined gain to generate the amplified detection signal S3, controls the gain at the time of amplification of the detection signal S1 such that a signal component of the reference signal Ss included in the amplified detection signal S3 can be cancelled by addition or subtraction of the amplified detection signal S3 and the reference signal Ss, and extracts (generates) a signal component of the AC voltage V1 out of the amplified detection signal S3 to output it as an output signal So. In this case, the signal component of the reference signal Ss included in the amplified detection signal S3 is the reference voltage component Vs1 included in the detection signal S1 (namely, a signal component having the same frequency as the reference signal Ss included in the amplified detection signal S3).

The processing section 33 executes, in the same manner as done in the voltage detection device 101 of the first embodiment, a storing operation, a voltage calculating operation, and an output operation to calculate RMS values, amplitudes, and other data of the AC voltage V1 and to show the data in the output section 35 comprising a display apparatus. Thus, detecting operation by the voltage detection device 102 completes detection of the AC voltage V1 of the detection object 4.

In the voltage detection device 102 according to the present embodiment, in the same manner as done in the voltage detection device 101 of the first embodiment, the signal extracting section 32 controls the amplitude of the amplified detection signal S3 in order for the signal component having the same frequency as the reference signal Ss, included in the amplified detection signal S3 to have its constant amplitude, and removes the signal component having the same frequency as the reference signal Ss included in the amplified detection signal S3 by addition or subtraction of the amplified detection signal S3 and the reference signal Ss, and then outputs the signal as the output signal So. Then, even when a coupling capacitance between the detection object 4 and the detecting electrode 12 (the static capacitance C0) is unknown, (regardless of the value of the static capacitance C0) the sensitivity on the AC voltage V1 is controlled to be constant. In other words, the amplitude of the voltage component derived from the detection object current Iv1 included in the output signal So is so controlled as to have a level corresponding to the amplitude of the AC voltage V1. As a result, detection of the voltage component included in the output signal So enables contact-free detection of the AC voltage V1 without calculation of the static capacitance C0.

In the voltage detection device 102 according to the present embodiment, in the same manner as done in the voltage detection device 101 of the first embodiment, the synchronous detection circuit 43 in the signal extracting section 32 detects the detection signal Vd showing the amplitude of the signal component on the reference signal Ss included in the amplified detection signal S3 or the output signal So through synchronous detection using the reference signal Ss, and the control circuit 44 controls the gain of the amplifying circuit 41 according to the detection signal Vd. Therefore, the voltage detection device 102 according to the present embodiment enables accurate detection of the signal component of the reference signal Ss through synchronous detection. As a result, the signal component of the reference signal Ss included in the amplified detection signal S3 can be canceled with high accuracy, and then the signal component of the reference signal Ss included in the output signal So can be significantly reduced so that accuracy of detection the AC voltage V1 can be further improved.

In the voltage detection device 102 according to the present embodiment as well, the signal extracting section 32 comprises the adding circuit 42, which carries out the process of canceling the signal component having an anti-phase (the anti-phase signal component) in comparison to the reference signal Ss included in the amplified detection signal S3 by using the reference signal Sr (the reference signal Ss in the present embodiment), as a canceling circuit, and the control circuit 44 controls the gain of the amplifying circuit 41 to enable canceling the anti-phase signal component (the signal component of the reference signal Ss) included in the amplified detection signal S3 input into the adding circuit 42 by using the reference signal Sr. Therefore, according to the present embodiment, the canceling circuit can be materialized with a simple circuit as the adding circuit, and the output signal So can be generated for sure while aiming at simplification of the machine structure.

In the voltage detection device 102 as well, making use of the relationship of the signal component of the reference signal Ss included in the amplified detection signal S3 having an anti-phase in comparison to the reference signal Sr (the reference signal Ss in the present embodiment), the adding circuit 42 as the canceling circuit cancels out the signal component of the reference signal Ss included in the amplified detection signal S3 and the reference signal Ss each other. Alternatively, in the detecting section 14A and the amplifying circuit 41, phases of the detection signal S1 and the amplified detection signal S3 can be reversed, and furthermore the reference signal Sr can also be output to the canceling circuit while being reversed. In such a configuration, the signal component of the reference signal Ss included in the amplified detection signal S3 may have the same phase as the reference signal Ss. According to such a configuration, using a subtracting circuit as the canceling circuit enables canceling out the signal component of the reference signal Ss included in the amplified detection signal S3 and the reference signal Ss each other.

In the present embodiment as described above, the reference signal Ss as the reference signal Sr is directly input into the canceling circuit (the adding circuit 42 in the embodiment described above). Alternatively, as indicated with a surrounding broken line in FIG. 4, the amplitude modifying section 36 may be placed between the reference signal output section 31 and the adding circuit 42 to multiply the amplitude of the reference signal Ss output from the reference signal output section 31 by k for change (wherein k is a positive real number) in the amplitude modifying section 36 and output the multiplied amplitude to the adding circuit 42 as a reference signal Sr1. According to this configuration, the detectable (measurable) range of the AC voltage V1 can be expanded by changing the magnification k at the amplitude modifying section 36, in the same manner as done in the voltage detection device 101.

In the voltage detection device 101 according to the first embodiment, as an example, connection between the insulator section 15 and amplifying circuit 41 is done directly, and so are connection between the reference signal output section 31 and the adding circuit 42 as well as connection between the reference signal output section 31 and the synchronous detection circuit 43. Meanwhile, in the voltage detection device 102 according to the second embodiment, as an example, connection between the detecting section 14A and the amplifying circuit 41 is done directly, and so are connection between the reference signal output section 31 and the adding circuit 42 as well as connection between the reference signal output section 31 and the synchronous detection circuit 43. Alternatively, though it is not shown in the drawings, a different configuration including a buffer placed between each couple of two components may be employed as required. Described above as an example is supplying the reference signal Ss output from the reference signal output section 31 to the synchronous detection circuit 43 while a level of the reference signal Ss being without any modification as it is. Alternatively, though it is not shown in the drawings, the level of the reference signal Ss may be reduced, as required, by using an attenuator including a divider resistor for example so as to supply the reduced reference signal to the synchronous detection circuit 43.

Though it is not shown in the drawing, the main circuit section 3 may comprise an A/D converter for converting the insulated detection signal S2 as an analog signal to digital data, and another A/D converter for converting the reference signal Ss as an analog signal, to be supplied from the reference signal output section 31 to the signal extracting section 32, to digital data so that all or part of the processing in the signal extracting section 32 can be executed digitally. In this case, the processing section 33 may have a function of the signal extracting section 32, and such an arrangement leads to a significant reduction in the number of circuit components. Functions of the processing section 33 and the signal extracting section 32 may be materialized with software, or otherwise with hardware (using a DSP (Digital Signal Processor) and/or a logic array).

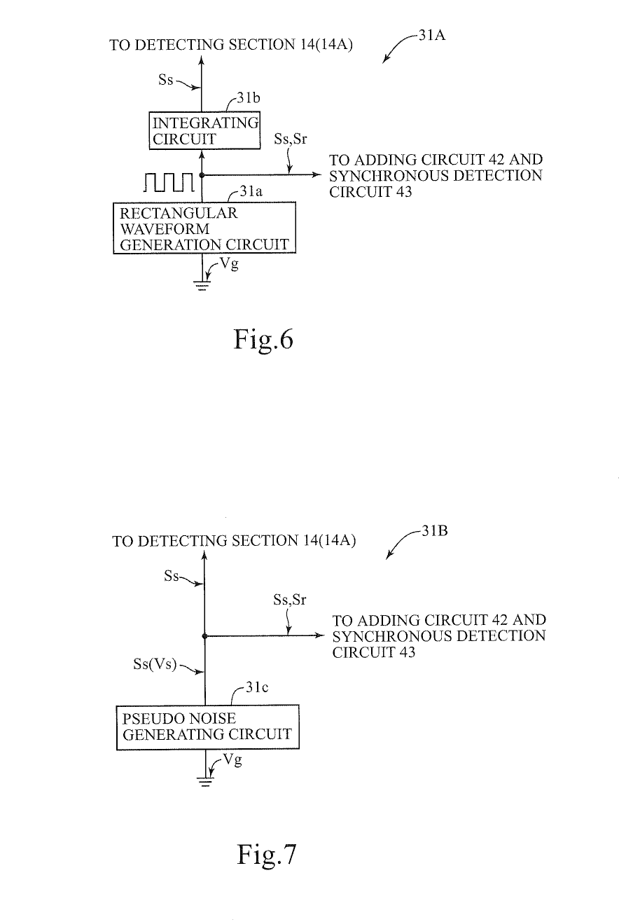

In the example described above, the reference signal output section 31 outputs an AC signal, having a constant frequency and a constant amplitude (for example, a sine-wave signal), as the reference signal Ss. Alternatively, it may be configured that a reference signal output section 31A shown in FIG. 6a outputs rectangular waveform signal instead of a sine-wave signal as the reference signal S. Specifically to describe, the reference signal output section 31A comprises a rectangular waveform generation circuit 31a for generating a rectangular waveform (a rectangular waveform signal), and an integrating circuit 31b for integrating the rectangular waveform (the rectangular waveform signal) and outputting it as an integrated rectangular waveform (an integrated rectangular waveform signal). The reference signal output section 31A outputs the rectangular waveform generated by the rectangular waveform generation circuit 31a to the synchronous detection circuit 43 of the signal extracting section 32, as the reference signal Ss, and also outputs the rectangular waveform to the adding circuit 42 of the signal extracting section 32, as the reference signal Sr. Furthermore, the reference signal output section 31A outputs the integrated rectangular waveform signal output from the integrating circuit 31b to the detecting section 14 (the detecting section 14A in the case of the voltage detection device 102), as the reference signal Ss. In this case, the detecting section 14 (the detecting section 14A) is connected in series to the static capacitance C0 through the detecting electrode 12, and therefore the reference current Is1, flowing through the circuit including the detecting section 14 (or 14A) and the static capacitance C0, is a signal resulted from differentiation of the reference signal Ss.

Accordingly, the reference current Is1, flowing through the circuit including the detecting section 14 (or 14A) and the static capacitance C0, can be made the same as the rectangular waveform signal that is output from the reference signal output section 31A to the signal extracting section 32 by integrating the reference signal Ss output from the reference signal output section 31A to the detecting section 14 (or 14A) in advance through the integrating circuit 31b, with configuring the rectangular waveform generation circuit 31a simply by making use of a logic circuit to simplify an entire part of the reference signal output section 31A. Thus, with the device configuration (specifically, a configuration of an entire part of the reference signal output section 31A) being simplified, the adding circuit 42 in the signal extracting section 32 can certainly cancel the anti-phase signal component having an anti-phase in comparison to the reference signal Ss included in the amplified detection signal S3 by using the reference signal Sr (the reference signal Ss in the present embodiment). As a result, the signal component of the AC voltage V1 can be extracted for sure out of the amplified detection signal S3 for outputting as the output signal So, and then the synchronous detection circuit 43 can certainly carry out synchronous-detection of the output signal So with the reference signal Ss.

It may be configured that a reference signal output section 31B shown in FIG. 7 comprises a pseudo noise generating circuit 31c to output a pseudo noise signal as the reference signal Ss. In this case, the reference signal output section 31B outputs a pseudo noise signal, generated by the pseudo noise generating circuit 31c, as the reference signal Ss to the detecting section 14 (or 14A) as well as the synchronous detection circuit 43 of the signal extracting section 32, and also outputs the pseudo noise signal as the reference signal Sr to the adding circuit 42 of the signal extracting section 32. The pseudo noise generating circuit 31c may be configured by using, for example, one of publicly known various shift registers, such as a linear feedback shift register of M-sequence, and may also be configured with a micro computer that generates pseudo noises through software processing. By using the reference signal output section 31B configured as described above, the voltage detection device 101 (101A), which is unlikely to become influenced with external disturbance (noise), can be materialized.

[Configuration Example of Inter-Line Voltage Detection Device]

Described below is an inter-line voltage detection device 51 using a plurality of voltage detection devices 101 according to the first embodiment.

At first, a configuration of the inter-line voltage detection device 51 is explained with reference to the accompanied drawings. Explained below is an example of detection of inter-line voltages over 3 electric paths R, S, and T of 3-phase 3-wire AC-voltage electric paths (3-phase: Phase-R, Phase-S, and Phase-T) (AC-voltage electric path: hereinafter, also called “Electric path”).

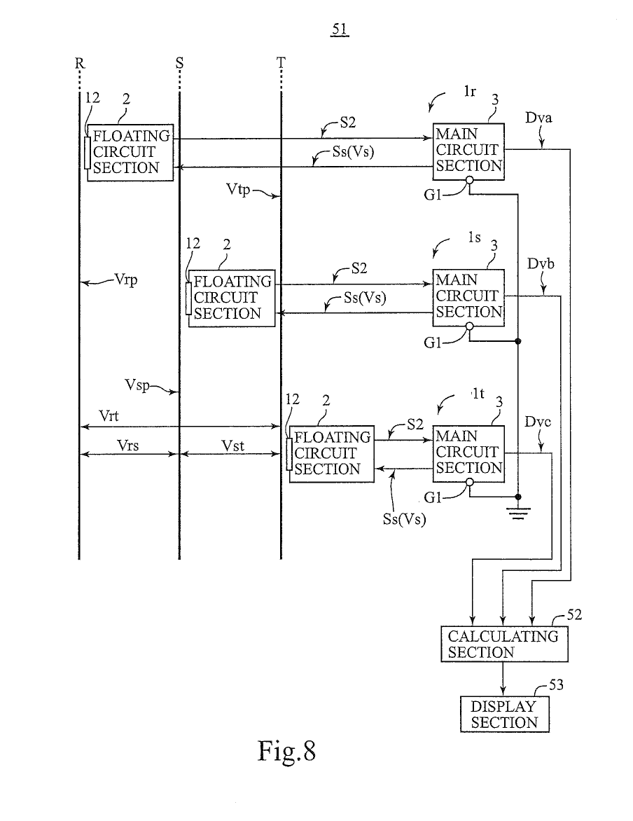

The inter-line voltage detection device 51 comprises, as an example shown in FIG. 8, voltage detection devices 101 of the same number (i.e., three) as that of electric paths R, S, and T (three voltage detection devices 101 hereinafter called “voltage detection device 101r”, “voltage detection device 101s”, and “voltage detection device 101t” in relation to electric paths R, S, and T, respectively, and also called “voltage detection device 101” comprehensively when being not distinguished specifically), a calculating section 52, and a display section 53 and is configured to be able to detect an inter-line voltage Vrs between the electric paths R and S, an inter-line voltage Vst between the electric paths S and T, and an inter-line voltage Vrt between the electric paths R and T, without physical contact.

The voltage detection devices 101, each of which is configured to be identical and comprises, as shown in FIG. 8, the floating circuit section 2 and the main circuit section 3 as described above, detect RMS values of AC voltages Vrp, Vsp and Vtp (objective AC voltages) corresponding to electric paths R, S, and T as detection objects, and then output the data showing the RMS values as detected data Dva, Dvb and Dvc. Hereinafter, the detected data Dva, Dvb and Dye are also called “detected data Dv” comprehensively when being not distinguished specifically. In the present embodiment, the output section 35 of each voltage detection device 101 is configured with a transmitting device for data transmission, and has a function to transmit the detected data Dva, Dvb and Dye received from the processing section 33 to the calculating section 52. Other constituent elements of the voltage detection device 101, except the output section 35, are the same as those of the above described configuration, and detailed descriptions of them are omitted.

The calculating section 52 comprises a CPU and a memory chip (which are not shown in the drawing) to execute an inter-line voltage calculating process for calculating (detecting) inter-line voltages by using the detected data Dv output from the voltage detection device 101. The calculating section 52 indicates results of the inter-line voltage calculating process at the display section 53: In the present embodiment, the display section 53 comprises a monitor such as an LCD, and may also comprise printing device such as a printer. Main circuit sections 3 are connected each other, as described later, at respective earth parts G1 (for example, housing parts of the main circuit sections 3) that work as their ground electric potential Vg. As an example, the calculating section 52 and the display section 53 are supplied with electric voltage for operation from a power supply unit (not shown) included in one of the three main circuit sections 3.

Described below is detecting operation of the inter-line voltage detection device 51.

As shown in FIG. 8 in the detecting operation, the floating circuit section 2 comes close to the electric path R in order for the voltage detection device 101r to detect the AC voltage Vrp of the electric paths R, and the detecting electrode 12 faces the corresponding electric path R. In the same manner, for the voltage detection devices 101s and 101t as well, the detecting electrodes 12 of the corresponding floating circuit sections 2 come close to, and face the electric paths S and T to detect the AC voltages Vsp and Vtp of the electric paths S and T. Thus, the static capacitance C0 (Refer to FIG. 1) is formed between each detecting electrode 12 and its corresponding one of the electric paths R, S, and T, and then the voltage detection devices 101r, 101s, and 101t start detecting the AC voltages Vrp, Vsp and Vtp of their corresponding electric paths R, S and T. In this case, as described above, the voltage detection devices 101r, 101s, and 101t can accurately detect the AC voltages Vrp, Vsp and Vtp by their processing sections 33 regardless of the capacitance value of the static capacitance C0.

In the voltage detection devices 101r, 101s, and 101t, their output sections 35 output the RMS values of the AC voltages Vrp, Vsp, and Vtp of the electric paths R, S, and T calculated by the processing sections 33, as the detected data Dva, Dvb and Dvc.

The calculating section 52 receives the detected data Dva, Dvb and Dvc output from each corresponding voltage detection device 101, and stores the data into the memory. Then, the calculating section 52 executes an inter-line voltage calculating process. Specifically, the calculating section 52 calculates a difference voltage of the RMS values of the AC voltages Vrp and Vsp, which are indicated as the detected data Dva and Dvb, to obtain (detect) the inter-line voltage Vrs between the electric paths R and S. In the same manner, the calculating section 52 calculates a difference voltage of the RMS values of the AC voltages Vsp and Vtp, which are indicated as the detected data Dvb and Dvc, to obtain (detect) the inter-line voltage Vst between the electric paths S and T, and also calculates a difference voltage of the RMS values of the AC voltages Vrp and Vtp, which are indicated as the detected data Dva and Dvc, to obtain (detect) the inter-line voltage Vrt between the electric paths R and T. Then, the calculating section 52 indicates the calculated inter-line voltages Vrs, Vst and Vrt at the display section 53.

Thus, even when a coupling capacitance (the static capacitance C0) between the detecting electrode 12 of each voltage detection device 101 and each of the electric paths R, S and T as the detection object of the voltage detection device 101 is unknown, the inter-line voltage detection device 51 enables accurate contact-fee detection of the inter-line voltages Vrs, Vst and Vrt by using the voltage detection device 101 without calculation of the coupling capacitance

[Another Configuration Example of Inter-Line Voltage Detection Device]

Described below is a inter-line voltage detection device 51A using a plurality of voltage detection devices 102 described above.

At first, a configuration of the inter-line voltage detection device 51A is explained with reference to the accompanied drawings. Components of the same configuration as the inter-line voltage detection device 51 are provided with the same reference numerals, and any redundant explanation is omitted. Explained below is an example of detection of inter-line voltages over 3-phase 3-wire electric paths R, S, and T.

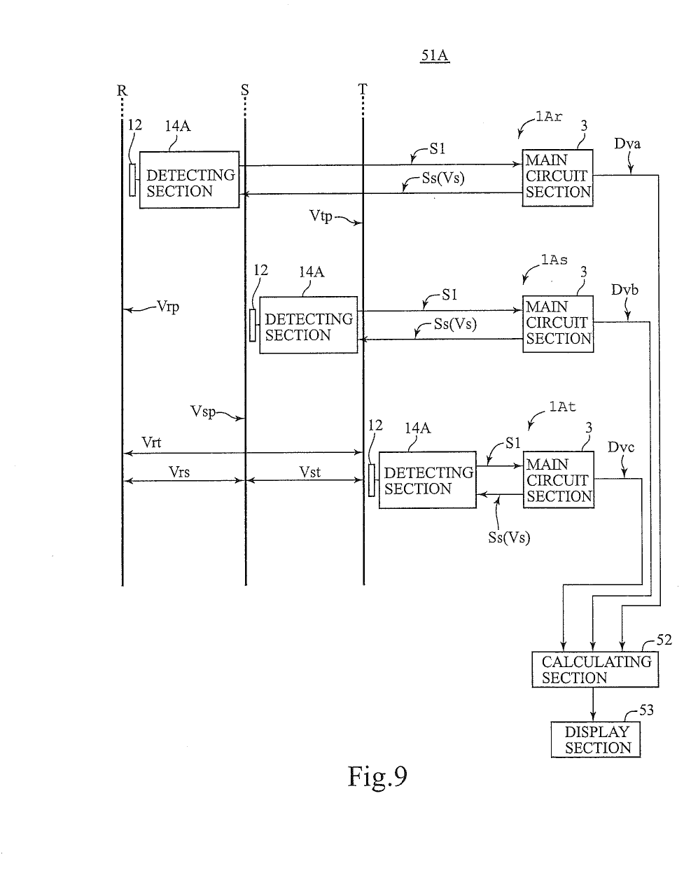

The inter-line voltage detection device 51A comprises, as an example as shown in FIG. 9, voltage detection devices 102 of the same number (i.e., 3) as that of electric paths R, S, and T (3 voltage detection devices 102: hereinafter called “voltage detection device 102r”, “voltage detection device 102s”, and “voltage detection device 102t” in relation to electric paths R, S, and T, respectively, and also called “voltage detection device 102” comprehensively when being not distinguished specifically), a calculating section 52, and a display section 53. The inter-line voltage detection device 51A is configured to be able to detect an inter-line voltage Vrs between the electric paths R and S, an inter-line voltage Vst between the electric paths S and T, and an inter-line voltage Vrt between the electric paths R and T, without physical contact.

The voltage detection devices 102, each of which is configured to be identical and comprises, as shown in FIG. 9, the detecting electrode 12, the detecting section 14A and the main circuit section 3 as described above, detect RMS values of AC voltages Vrp, Vsp and Vtp (objective AC voltages) corresponding to electric paths R, S, and T as detection objects, and then output the data showing the RMS values as detected data Dva, Dvb and Dvc. In the present embodiment, the output section 35 of each voltage detection device 102 is configured with a transmitting device for data transmission, and has a function to transmit the detected data Dva, Dvb and Dvc received from the processing section 33 to the calculating section 52. Other constituent elements of the voltage detection device 102, except the output section 35, are the same as those of the above described configuration, and detailed descriptions of them are omitted. Since the calculating section 52 and the display section 53 are also the same as those of the inter-line voltage detection device 51, detailed descriptions of them are omitted.

Described below is detecting operation of the inter-line voltage detection device 51A.

As shown in FIG. 9 in the detecting operation, the detecting electrodes 12 comes close to, and faces the electric path R, in order for the voltage detection device 102r to detect the AC voltage Vrp of the electric path R. In the same manner, for the voltage detection devices 102s and 102t as well, the detecting electrodes 12 come close to, and face the corresponding electric paths S and T to detect the AC voltages Vsp and Vtp of the electric paths S and T. Thus, the static capacitance C0 (refer to FIG. 4) is formed between each detecting electrode 12 and its corresponding one of the electric paths R, S, and T, and then the voltage detection devices 102r, 102s, and 102t start detecting the AC voltages Vrp, Vsp and Vtp of their corresponding electric paths R, S and T. In this case, as described above, the voltage detection devices 102r, 102s, and 102t can accurately detect the AC voltages Vrp, Vsp and Vtp by their processing sections 33 regardless of the capacitance value of the static capacitance C0.

In the voltage detection devices 102r, 102s, and 102t, their output sections 35 output the RMS values of the AC voltages Vrp, Vsp, and Vtp of the electric paths R, S, and T calculated by the processing sections 33, as the detected data Dva, Dvb and Dvc, respectively.

The calculating section 52 receives the detected data Dva, Dvb and Dvc output from each corresponding voltage detection device 102, and stores the data into the memory. Then, the calculating section 52 executes an inter-line voltage calculating process to calculate a difference voltage of the RMS values of the AC voltages Vrp and Vsp, which are indicated as the detected data Dva and Dvb, for obtaining the inter-line voltage Vrs between the electric paths R and S. Furthermore, the calculating section 52 calculates a difference voltage of the RMS values of the AC voltages Vsp and Vtp, which are indicated as the detected data Dvb and Dvc, to obtain the inter-line voltage Vst between the electric paths S and T, and also calculates a difference voltage of the RMS values of the AC voltages Vrp and Vtp, which are indicated as the detected data Dva and Dvc, to obtain the inter-line voltage Vrt between the electric paths R and T. Then, the calculating section 52 indicates the calculated inter-line voltages Vrs, Vst and Vrt at the display section 53.

Thus, even when a coupling capacitance (the static capacitance C0) between the detecting electrode 12 of each voltage detection device 102 and each of the electric paths R, S and T as the detection object of the voltage detection device 102 is unknown, the inter-line voltage detection device 51A enables accurate contact-fee detection of the inter-line voltages Vrs, Vst and Vrt by using the voltage detection device 102 without calculation of the coupling capacitance.

[Modifications]

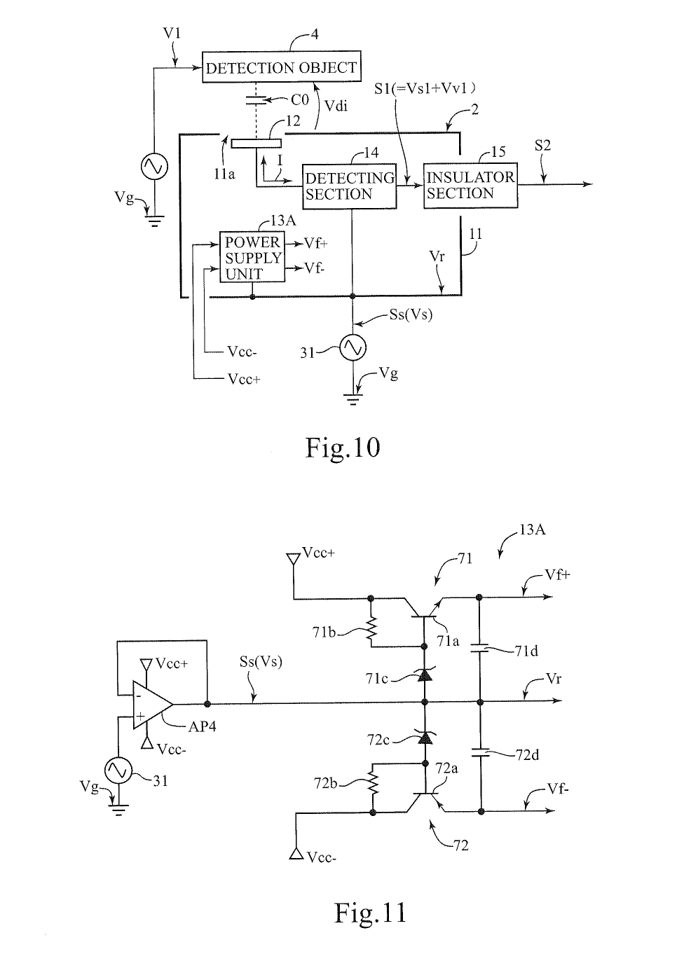

Described above as the power supply unit 13 for creating the floating voltages Vf+ and Vf− to be used in the voltage detection device 101 according to the first embodiment are a configuration including a battery and a DC/DC converter (which are not shown in the drawing), as well as another configuration in which supplying an AC voltage into the guard electrode 11 from the outside of the guard electrode 11 is done through a transformer instead of using the battery, while an external power supply line being electrically insulated, and then a rectifying smoother section placed in the guard electrode 11 converts the AC voltage into a DC voltage to supply it to the DC/DC converter. Furthermore, still another configuration may also be employed, as shown in FIG. 10, in which a power supply unit 13A is used for creating the floating voltages Vf+ and Vf− described above, while having the voltage Vr of the guard electrode 11, namely the voltage Vs of the reference signal Ss, as a datum (0 volt), with reference to voltages for operation (i.e., a positive voltage Vcc+ and a negative voltage Vcc− generated on the basis of the ground electric potential Vg) supplied from a power supply unit, not shown in the figure, for constituent elements of the main circuit section 3 (such as the reference signal output section 31, the signal extracting section 32, and the processing section 33).

The power supply unit 13A comprises, as shown in FIG. 11, a first series power supply circuit 71 and a second series power supply circuit 72. The first series power supply circuit 71 generates the floating voltage Vf+, which is a certain positive voltage in comparison with the voltage Vr of the guard electrode 11, with reference to the positive voltage Vcc+under conditions where the voltage Vr of the guard electrode 11 being 0 volt. The second series power supply circuit 72 generates the floating voltage Vf− (wherein an absolute value of a difference between the floating voltage Vf− and the voltage Vr becomes equal to an absolute value of a difference between the floating voltage Vf+ and the voltage Vr), which is a negative voltage having the same absolute value as the floating voltage Vf+has, in comparison with the voltage Vr of the guard electrode 11, with reference to the negative voltage Vcc−. Concretely to describe, the first series power supply circuit 71 includes an NPN bipolar transistor 71a (hereinafter, also called a “first transistor 71a”), a first resistor 71b, a first Zener diode 71c (a Zener voltage Vz), and a first condenser 71d. In this case, with respect to the first transistor 71a, its collector terminal is connected to a supply line of the positive voltage Vcc+, its emitter terminal is connected to an output line of the floating voltage Vf+, and its base terminal is connected to a cathode terminal of the first Zener diode 71c. An anode terminal of the first Zener diode 71c is connected to a supply line of the voltage Vr. One end and the other end of the first resistor 71b are connected to the collector terminal and the base terminal of the first transistor 71a, respectively. One end and the other end of the first condenser 71d are connected to the emitter terminal of the first transistor 71a and the supply line of the voltage Vr, respectively.

The second series power supply circuit 72 comprises an PNP bipolar transistor 72a (hereinafter, also called a “second transistor 72a”), a second resistor 72b, a second Zener diode 72c (a Zener voltage Vz being the same as the first Zener diode 71c has), and a second condenser 72d. In this case, with respect to the second transistor 72a, its base-emitter terminal voltage Vbe is set to be the same as that of the first transistor 71a, its collector terminal is connected to a supply line of the negative voltage Vcc−, its emitter terminal is connected to a output line of the floating voltage Vf−, and its base terminal is connected to a anode terminal of the second Zener diode 72c. A cathode terminal of the second Zener diode 72c is connected to the supply line of the voltage Vr. One end and the other end of the second resistor 72b are connected to the collector terminal and the base terminal of the second transistor 72a, respectively. One end and the other end of the second condenser 72d are connected to the emitter terminal of the second transistor 72a and the supply line of the voltage Vr, respectively.

According to the configuration described above, in the power supply unit 13A, the first series power supply circuit 71 generates the floating voltage Vf+(=Vr+Vz−Vbe) from the positive voltage Vcc+, and outputs the voltage, and the second series power supply circuit 72 generates the floating voltage Vf−(=Vr−Vz+Vbe) from the negative voltage Vcc−, and outputs the voltage. Specifically, in the first series power supply circuit 71, the first Zener diode 71c generates the Zener voltage Vz at its cathode terminal with receiving a current from the first resistor 71b, and the first transistor 71a, whose base terminal is set to have the Zener voltage Vz, generates a voltage (Vz−Vbe) at its emitter terminal, with reference to the anode terminal of the first Zener diode 71c. Thus, the first series power supply circuit 71 generates and outputs the floating voltage Vf+having its voltage (Vr+Vz−Vbe) with reference to the ground electric potential Vg. In the second series power supply circuit 72, the second Zener diode 72c generates the Zener voltage Vz at its anode terminal with receiving a current from the second resistor 72b, and the second transistor 72a, whose base terminal is set to have the Zener voltage Vz, generates a voltage (−Vz+Vbe) at its emitter terminal, with reference to the anode terminal of the second Zener diode 72c. Thus, the second series power supply circuit 72 generates and outputs the floating voltage Vf− having its voltage (Vr−Vz+Vbe) with reference to the ground electric potential Vg.

In other words, as far as the voltage Vr changes under conditions where the voltage (Vr+Vz−Vbe) does not reach the positive voltage Vcc+, and the voltage (Vr−Vz+Vbe) does not reach the negative voltage Vcc−, the power supply unit 13A generates and outputs, with tracking the change of the voltage Vr, the floating voltage Vf+ and the floating voltage Vf− that are a positive voltage and a negative voltage, respectively, having the same absolute value |Vz−Vbe| with reference to the voltage Vr. Thus, the circuits in the floating circuit section 2 receive the floating voltages Vf+ and Vf− to operate normally. As a result, the insulated detection signal S2 is output normally from the floating circuit section 2. Therefore, the use of the power supply unit 13A results in avoidance of using expensive components such as a battery and a transformer so that production costs of the voltage detection device 1 can substantially be reduced. Though it is not shown, each of the series power supply circuits 71 and 72 may additionally comprise a publicly known over-current protection circuit or over-voltage protection circuit.

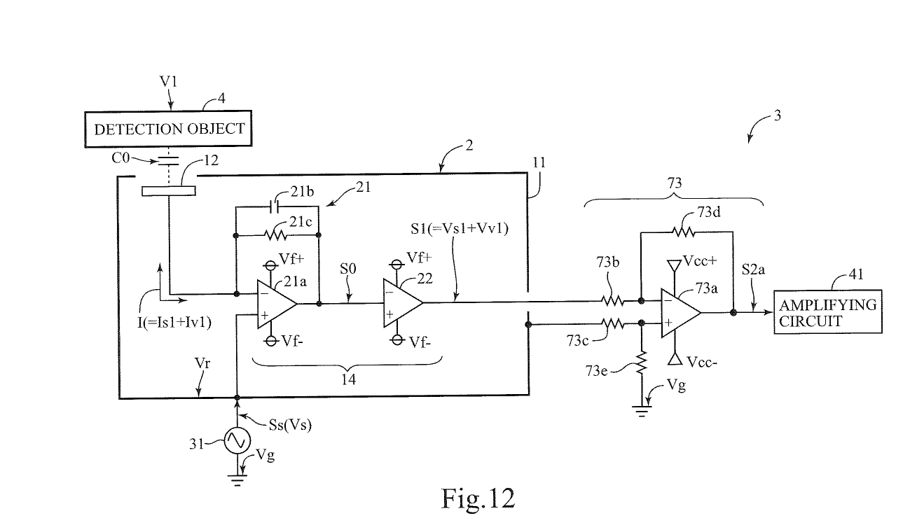

Described above is a configuration of the floating circuit section 2 including the insulator section 15, in which the detection signal S1 detected by the detecting section 14 is converted and output as the insulated detection signal S2 electrically insulated from the detection signal 51. Alternatively, it may be configured that the floating circuit section 2 does not comprise the insulator section 15 as shown in FIG. 12. In such a configuration, the detection signal S1 and a signal of the voltage Vr are output in a pair from the floating circuit section 2 to the main circuit section 3 such that a differential amplifying circuit 73 placed in the main circuit section 3 receives the detection signal S1 and the voltage Vr and a detection signal S2a indicating a difference between the detection signal S1 and the voltage Vr is output to the amplifying circuit 41 instead of the insulated detection signal S2.

The differential amplifying circuit 73 may comprise, as an example shown in FIG. 12, an operational amplifier 73a, an input resistor 73b placed between an inverting input terminal of the operational amplifier 73a and the amplifying circuit 22 of the floating circuit section 2, an input resistor 73c placed between a non-inverting input terminal of the operational amplifier 73a and the guard electrode 11 of the floating circuit section 2, a feedback resistor 73d for the operational amplifier 73a, and a resistor 73e placed between the non-inverting input terminal of the operational amplifier 73a and the ground electric potential Vg. In the configuration shown in FIG. 12, either of the power supply units 13 and 13A described above may be used as a power supply unit for supplying the floating voltages Vf+ and Vf− to each component of the floating circuit section 2.

In relation to the reference signal output section 31, as shown in FIG. 11, an operational amplifier AP4 configured as a voltage-follower circuit may be added to the reference signal output section 31 in order for the section as a whole to function as a new reference signal output section so that the reference signal Ss generated in the reference signal output section 31 is output with a still lower impedance.

As explained in the embodiments described above, the gain of the amplifying circuit 41 is controlled in such a way that the amplitude of the signal component of the reference signal included in the amplified detection signal output from the amplifying circuit 41 has a value, with which the reference signal and the signal component of the reference signal included in the amplified detection signal are canceled out each other by addition or subtraction of the reference signal output from the reference signal output section 31 (or 31A, or 31B) and the amplified detection signal output from the amplifying circuit 41, and then a signal generated by canceling the signal component of the reference signal included in the amplified detection signal therefrom is extracted as the signal component of the objective AC voltage. Alternatively, the gain of the amplifying circuit 41 may also be controlled in such a different way that that amplitude of the signal component of the reference signal included in the amplified detection signal output from the amplifying circuit 41 has a predetermined constant value, and a signal component obtained by removing at least the frequency component of the reference signal from the amplified detection signal is extracted. Described below is another embodiment in such a different way.

### Third Embodiment

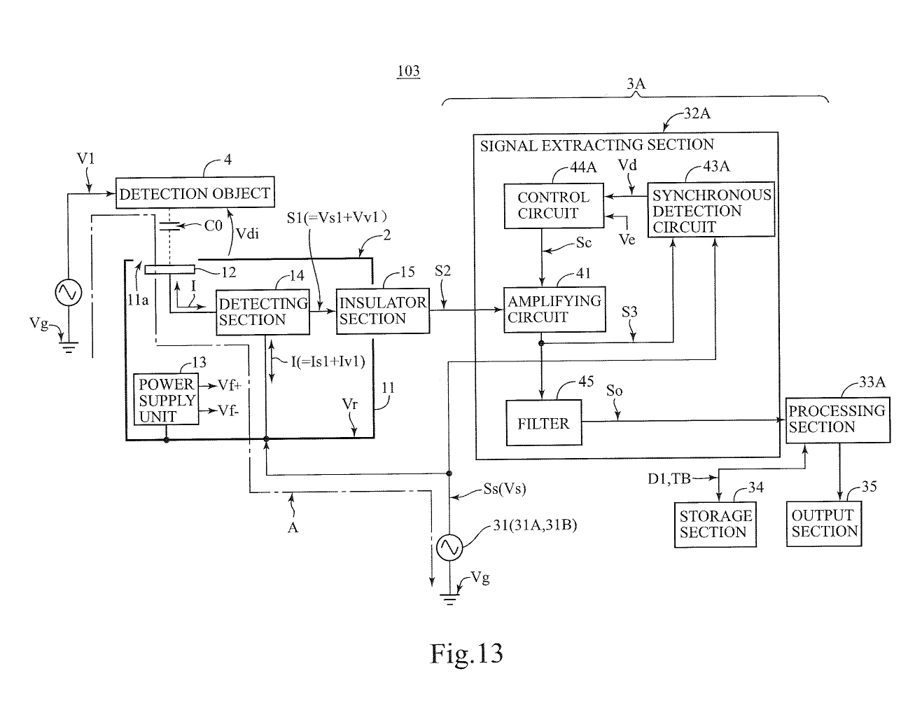

A voltage detection device 103 of a third embodiment in accordance with the present invention is a contact-free type voltage detection device comprising, as shown in FIG. 13, a floating circuit section 2 and a main circuit section 3A. The voltage detection device 101 is configured to be able to detect, by taking a ground electric potential Vg as a reference, an AC voltage V1 (an objective AC voltage) arising on a detection object 4 without physical contact. Except configuration of a signal extracting section 32A of the main circuit section 3A and operation of a processing section 33A, the configuration and operation of the voltage detection device 103 are the same as those of the voltage detection device 101 shown in FIG. 1. Then, all the same components are provided with the same reference numerals, and any redundant explanation is omitted. Explanation is mainly given regarding the signal extracting section 32A and the processing section 33A that are placed differently from the voltage detection device 101.

The signal extracting section 32A comprises, as an example shown in FIG. 13, the amplifying circuit 41, a synchronous detection circuit 43A, a control circuit 44A, and a filter 45. The signal extracting section 32A amplifies the insulated detection signal S2 to generate the amplified detection signal S3, in order for the signal component having the same frequency as the reference signal Ss, included in the amplified detection signal S3, to have its constant amplitude (an amplitude specified beforehand), and removes the signal component, having the same frequency as the reference signal Ss, from amplified detection signal S3, to output as the output signal So. In this case, the signal component of the reference signal Ss, included in the amplified detection signal S3, is a signal component due to the reference voltage component Vs1 included in the detection signal S1 according to the output of the reference signal Ss (imposed on) to the guard electrode 11 (namely, a signal component having the same frequency as the reference signal Ss included in the amplified detection signal S3).

Specifically, the amplifying circuit 41 receives the insulated detection signal S2 and amplifies the insulated detection signal S2 with a gain (the gain may be greater or smaller than or equal to 1) set by a level (a DC voltage level) of a control signal Sc (specifically, a control voltage) output from the control circuit 44A and generates the amplified detection signal S3 to output. As the amplifying circuit 41, the one shown in FIG. 3 for the first embodiment may be employed in this case.

The synchronous detection circuit 43A receives the amplified detection signal S3 from the amplifying circuit 41 as well as the reference signal Ss from the reference signal output section 31 and generates the detection signal Vd through synchronous-detection of the amplified detection signal S3 with the reference signal Ss to output.

The control circuit 44A generates the control signal Sc, according to the voltage of the detection signal Vd entered and a target voltage Ve (a voltage internally generated, or externally received, as an example, a voltage received externally outside the control circuit 44A in the present embodiment), and outputs the control signal Sc. Specifically, the control circuit 44A increases the voltage level when the voltage of the detection signal Vd is lower than the target voltage Ve, decreases the voltage level when the voltage of the detection signal Vd is higher than the target voltage Ve, and then outputs the control signal Sc. Based on the configuration described above, feedback control for the gain (amplification ratio) of the amplifying circuit 41 is carried out in the signal extracting section 32A by the synchronous detection circuit 43A and the control circuit 44A, wherein the control circuit 44A controls the gain of the amplifying circuit 41 according to the detection signal Vd so as to make the anti-phase signal component (the signal component having the same frequency as the reference signal Ss) included in the amplified detection signal S3 have a constant amplitude. In this case, any optional value can be adopted as the amplitude specified beforehand. At the time of creating the voltage calculation table TB, to be described later, which is used through the voltage calculating operation in the processing section 33A, the voltage calculation table TB is created on the basis of the digital data D1 obtained by the processing section 33A under conditions where the synchronous detection circuit 43A and the control circuit 44A are carrying out feedback controls for the gain of the amplifying circuit 41 with using the adopted value as the pre-specified amplitude.

The filter 45 receives the amplified detection signal S3 output from the amplifying circuit 41, and extracts the signal component of the AC voltage V1 from the amplified detection signal S3 to output it as the output signal So. The filter 45, which nay be configured, for example, by a passive filter circuit comprising a band pass filter and/or a low-pass filter, and/or an active filer circuit, prevents the signal component having the same frequency as the reference signal Ss from passing through and allows the voltage component (the signal component having the same frequency as the AC voltage V1) derived from the detection object current Iv1 due to the AC voltage V1 of the detection object 4 to pass through. According to this configuration, the signal extracting section 32A generates the output signal So including the voltage component according to the detection object current Iv1 due to the AC voltage V1 of the detection object 4, and outputs the signal So.

In the voltage detection device 103, according to the static capacitance C0 formed between the detection object 4 and the detecting electrode 12, the reference current Is1 included in the current signal I and the detection object current Iv1 fluctuate in the same ratio, and furthermore the reference voltage component Vs1 included in the detection signal S1 and the detection object voltage component Vv1 also fluctuate in the same ratio. Therefore, the anti-phase signal component (the signal component having the same frequency as the reference signal Ss) and the signal component having the same frequency as the AC voltage V1, both included in the amplified detection signal S3, are also fluctuate in the same ratio. In the signal extracting section 32A, through the feedback control as described above, the amplified detection signal S3 is generated by the amplifying circuit 41 in such a way that the amplitude of the anti-phase signal component (the signal component having the same frequency as the reference signal Ss) included in the signal S3 becomes constant. Thus, in the voltage detection device 103 with the configuration of the present embodiment, the voltage component derived from the detection object current Iv1 included in the output signal So makes its amplitude correspond to (be in proportion to) the amplitude of the AC voltage V1 that arises on the detection object 4, regardless of the static capacitance C0. Accordingly, the output signal So output from the signal extracting section 32A becomes a signal having its amplitude that changes in proportion to the amplitude of the AC voltage V1 of the detection object 4.

The processing section 33A is configured to comprise an A/D converter and a CPU (both the two are not shown in the drawing) to execute storing operation, in which a voltage waveform (level) of the output signal So is sampled by using a sampling clock with a predetermined frequency, and converted into digital data D1, and then the data is stored in the storage section 34, voltage calculating operation for calculating the AC voltage V1 based on the digital data D1, and output operation for outputting the AC voltage V1 calculated. The storage section 34 comprises a ROM, and a RAM such that a voltage calculation table TB to be used through the voltage calculating operation in the processing section 33A are stored in advance.

Described below is an outline of procedures of creating the voltage calculation table TB in the present embodiment. As an example, the voltage calculation table TB is created through obtaining the digital data D1 with changing the amplitude of the AC voltage V1 generated at the detection object 4 by the predetermined voltage step under a condition where feedback control for the gain (amplification ratio) of the amplifying circuit 41 is carried out by the synchronous detection circuit 43A, wherein the control circuit 44A controls the gain of the amplifying circuit 41 based on the detection signal Vd so as to make the anti-phase signal component (the signal component having the same frequency as the reference signal Ss) included in the amplified detection signal S3 have a constant amplitude (the pre-specified amplitude), associating the obtained digital data D1 with the AC voltage V1 changed by the predetermined voltage step and storing the digital data D1 together with the voltage value of the AC voltage V1. According to this configuration, the processing section 33A retrieves the voltage values of the AC voltage V1 corresponding to the obtained digital data D1 by reference to the voltage calculation table TB so as to enable calculation of the AC voltage V1 of the detection object 4. The output section 35 in the present embodiment, as an example, is configured with a display apparatus to show a waveform of the AC voltage V1 and calculated voltage parameters (such as amplitudes and RMS values) according to the output operation by the processing section 33A.

Described below is detecting operation for detecting the AC voltage V1 of the detection object 4 by the voltage detection device 103.

In the same manner as done in the first embodiment, the insulated detection signal S2 electrically insulated from the detection signal S1 is output from the insulator section 15 of the floating circuit section 2. In the signal extracting section 32A of the main circuit section 3A as shown in FIG. 13, the amplifying circuit 41 receives the insulated detection signal S2, amplifies the insulated detection signal S2 with the gain set by the voltage level of the control signal Sc output from the control circuit 44A, generates the amplified detection signal S3 in such a way that the signal component having the same frequency as the reference signal Ss has its constant amplitude, and then outputs the amplified detection signal S3.

As an example, the synchronous detection circuit 43A receives the amplified detection signal S3 as well as the reference signal Ss, generates the detection signal Vd, which changes its voltage according to the change in the amplitude of the signal component of the reference signal Ss included in the amplified detection signal S3, through synchronous-detection of the amplified detection signal S3 with the reference signal Ss, and outputs the detection signal Vd.

The control circuit 44A generates the control signal Sc according to the voltage of the detection signal Vd entered and the target voltage Ve, and outputs the control signal Sc. Specifically, the control circuit 44A increases the voltage level when the voltage of the detection signal Vd is lower than the target voltage Ve, decreases the voltage level when the voltage of the detection signal Vd is higher than the target voltage Ve, and then outputs the control signal Sc. According to the configuration described above, feedback control for the gain (amplification ratio) of the amplifying circuit 41 is carried out in the signal extracting section 32A by the synchronous detection circuit 43A and the control circuit 44A, wherein the control circuit 44A controls the gain of the amplifying circuit 41 according to the detection signal Vd so as to make the anti-phase signal component (the signal component having the same frequency as the reference signal Ss) included in the amplified detection signal S3 have a constant amplitude (the pre-specified amplitude: the amplitude used at the time of creating the voltage calculation table TB). Thus, the amplifying circuit 41 amplifies the insulated detection signal S2 entered, generates the amplified detection signal S3 in such a way that the signal component having the same frequency as the reference signal Ss has its constant amplitude (the pre-specified amplitude described above), and then outputs the amplified detection signal S3. The filter 45 receives the amplified detection signal S3 output from the amplifying circuit 41, and extracts the signal component of the AC voltage V1 from the amplified detection signal S3 to output the signal as the output signal So.

The processing section 33A executes storing operation to receive the output signal So, to convert the signal into the digital data D1 and to store the data into the storage section 34. Subsequently, the processing section 33A executes voltage calculating operation, in which the processing section 33A reads out the digital data D1 stored in the storage section 34 and retrieves the AC voltage V1 corresponding to the digital data D1 read out by reference to the voltage calculation table TB. The processing section 33A furthermore calculates, for example, amplitudes, RMS values, and other data of the AC voltage V1 by using the AC voltage V1 retrieved, and stores the calculated data into the storage section 34. Finally, the processing section 33A executes output operation to show the RMS values, amplitudes, and other data of the AC voltage V1, which the storage section 34 stores, in the output section 35 including the display device. Thus, the detecting operation by the voltage detection device 103 completes detection of the AC voltage V1 of the detection object 4. For the output operation, it may be configured alternatively that the processing section 33 shows the voltage waveform of the AC voltage V1 in the output section 35 by using the AC voltage V1 obtained.

In the present embodiment, the reference signal output section 31 outputs the reference signal Ss to the guard electrode 11, and the detecting section 14, being supplied with the floating voltage Vf+ and the floating voltage Vf− for its operation, outputs the detection signal S1 that changes its amplitude according to the AC potential difference (V1−Vr), in accordance with a current signal I flowing between the detection object 4 and the guard electrode 11 through the detecting electrode 12 with a current value according to an AC potential difference between the AC voltage V1 and the voltage Vr of the guard electrode 11 (V1−Vr). The insulator section 15 receives the detection signal S1 and then outputs a signal as the insulated detection signal S2. The signal extracting section 32A controls the amplitude of the insulated detection signal S2 in such a way that the amplitude of the signal component, having the same frequency as the reference signal Ss included in the insulated detection signal S2, becomes equal to a predetermined amplitude, or in other words, the amplitude of the signal component becomes constant, and the signal extracting section 32A generates the amplified detection signal S3. Then, the signal extracting section 32A removes the signal component having the same frequency as the reference signal Ss included in the amplified detection signal S3 by addition or subtraction of the amplified detection signal S3 having its amplitude controlled as described above and the reference signal Ss output from the reference signal output section 31, and outputs the signal as the output signal So.

According to the present embodiment, the signal extracting section 32A controls the amplitude of the amplified detection signal S3 in order for the signal component having the same frequency as the reference signal Ss to have its constant amplitude. Thus, even when coupling capacitance between the detection object 4 and the detecting electrode 12 (the static capacitance C0) is unknown, (regardless of the value of the static capacitance C0) the sensitivity on the AC voltage V1 is controlled to be constant. In other words, the amplitude of the voltage component derived from the detection object current Iv1 included in the output signal So is so controlled as to have a level corresponding to the amplitude of the AC voltage V1. As a result, detection of the voltage component included in the output signal So enables contact-free detection of the AC voltage V1 without calculation of the static capacitance C0.

In the signal extracting section 32A of the present embodiment, the synchronous detection circuit 43A detects the detection signal Vd showing the amplitude of the signal component on the reference signal Ss included in the amplified detection signal S3 through synchronous detection using the reference signal Ss, and the control circuit 44A controls the gain of the amplifying circuit 41 according to the detection signal Vd. Therefore, the voltage detection device of the present embodiment enables accurate detection of the signal component of the reference signal Ss through synchronous detection. As a result, the amplitude of the signal component of the reference signal Ss included in the amplified detection signal S3 can be controlled stably with high accuracy so that accuracy of detecting the AC voltage V1 can be further improved.

As a method for generating the output signal So through extraction of the signal component of the AC voltage V1 from the amplified detection signal S3, a method of digital signal processing on the amplified detection signal S3 in the processing section 33A may be used. According to the present embodiment, by the use of the filter 45 that can be configured with a publicly known filter circuit having the characteristics described above, the AC voltage V1 is extracted. Therefore, despite the simple configuration, the output signal So including the voltage component generated according to the detection object current Iv1 can be generated at low cost. Furthermore, according to the present embodiment, changing the target voltage Ve makes it possible to change the range of the detectable range of the AC voltage V1.

According to the present embodiment, owing to being provided the processing section 33A for detecting the AC voltage V1 in accordance with the output signal So, the voltage detection device enables the processing section 33A to detect the AC voltage V1 at constant interval, enables the storage section 34 to store data of the AC voltage V1 detected, and enables the output section 35 to show the voltage waveform of the AC voltage V1 based on the data of the AC voltage V1 stored in the storage section 34.

In the present embodiment, the processing section 33A calculates the voltage values of the AC voltage V1 in accordance with the output signal So. As an example, the processing section 33A receives the output signal So including the voltage component (namely, the voltage component having the same frequency as that of the AC voltage V1) generated according to the detection object current Iv1 to obtain the digital data D1, and then by reference to the voltage calculation table TB, the processing section 33A retrieves the voltage values of the AC voltage V1 in accordance with the digital data D1 obtained to calculate the voltage values of the AC voltage V1 of the detection object 4. Therefore, the voltage values of the AC voltage V1 themselves can be detected according to the present embodiment.

In the third embodiment described above, by accommodating the detecting electrode 12, the power supply unit 13, the detecting section 14, and the insulator section 15 within the guard electrode 11, the floating circuit section 2 is prepared separately from the main circuit section 3 to increase CMRR (Common Mode Rejection Ratio) and to enable detection of the AC voltage V1 in a higher range. If it is not required to operate the detecting section 14 under floating condition (for example, if the AC voltage V1 is relatively low, or no high CMRR is requested), an alternative configuration using neither the guard electrode 11, the power supply unit 13, nor the insulator section 15 may also be used as in the second embodiment. An embodiment using such a configuration is described below.

### Fourth Embodiment

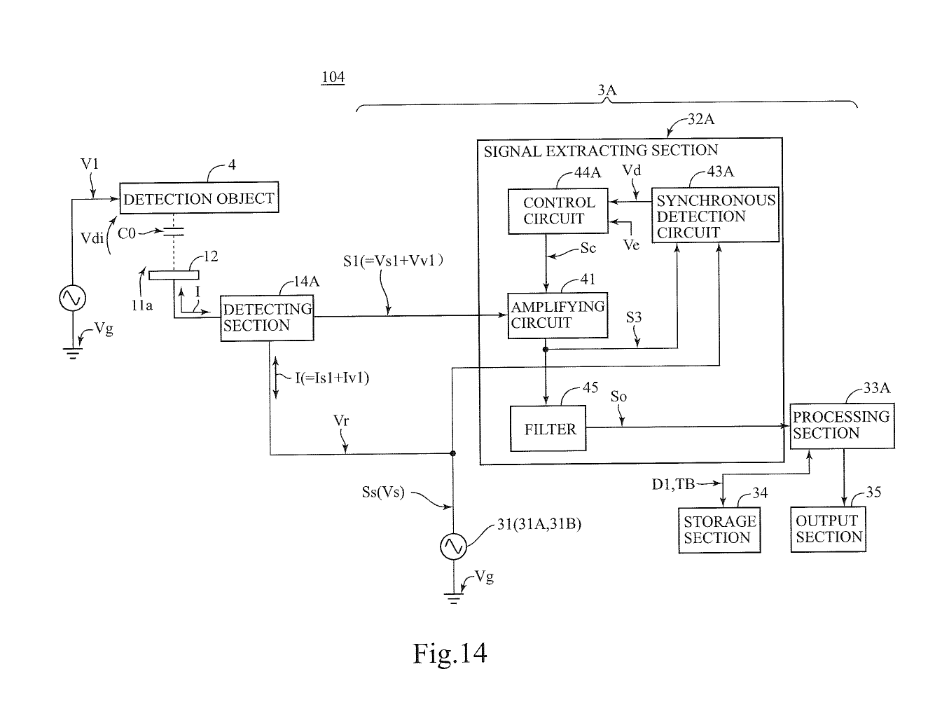

A voltage detection device 104 of a fourth embodiment according to the present invention comprises, as shown in FIG. 14, a detection electrode 12 and a detecting section 14A, instead of the floating circuit section 2 of the voltage detection device 103 according to the third embodiment, but same as the voltage detection device 102 according to the second embodiment. Namely, the voltage detection device 104 comprises the detection electrode 12, the detecting section 14A, and a main circuit section 3A. The voltage detection device 104 is configured to be able to detect the AC voltage V1 arising on a detection object 4 without physical contact. With respect to the detection electrode 12 and the main circuit section 3A, the same configuration as that of the voltage detection device 103 according to the third embodiment is uses, and with respect to the detecting section 14A, the same configuration as that of the voltage detection device 102 according to the second embodiment is used. Then, these components are provided with the same reference numerals, and any redundant explanation is omitted.

The inter-line voltage detection device 51 shown in FIG. 8 can be configured by using a plurality of the voltage detection devices 103 according to the third embodiment, in the same manner as using a plurality of the voltage detection devices 101 according to the first embodiment. Furthermore, the inter-line voltage detection device 51A shown in FIG. 9 can be configured by using a plurality of the voltage detection devices 104 according to the fourth embodiment, in the same manner as using a plurality of the voltage detection devices 102 according to the second embodiment.

For improvement of reliability of the detected AC voltage data, an additional function may be employed to check (diagnose) to see if the voltage detection (measurement) is carried out properly. Such an embodiment is described below.

### Fifth Embodiment

A voltage detection device 105 of a fifth embodiment in accordance with the present invention is a contact-free type voltage detection device comprising, as shown in FIG. 15, a floating circuit section 2 and a main circuit section 3B. The voltage detection device 105 is configured to be able to detect, by taking the ground electric potential Vg as a reference, the AC voltage V1 (the objective AC voltage) arising on the detection object 4 without physical contact. Except an additional configuration with a filter 38 and operation of a processing section 33B in the main circuit section 3B, the configuration and operation of the voltage detection device 105 are the same as those of the voltage detection device 101 shown in FIG. 1. All the same components are provided with the same reference numerals, and any redundant explanation is omitted. Explanation is mainly given regarding components and sections that are placed differently from the voltage detection device 101.

The filter 38 (for example, a band-pass filter) selectively allows the signal component having the same frequency as the reference signal Ss to pass through. As shown with a broken line in FIG. 15, the filter 38 receives the insulated detection signal S2 detected at a point “A”, which is an entrance point from the insulator section 15 into the signal extracting section 32, and then extracts a signal component Ss2 of the reference signal Ss included in the insulated detection signal S2, and outputs the signal component Ss2 to the processing section 33B.

The processing section 33B comprises an A/D converter and a CPU (both the two are not shown in the drawing) to execute storing operation, in which a voltage waveform (level) of the output signal So is sampled by using a sampling clock with a predetermined frequency, and converted into digital data D1, and then the data is stored in the storage section 34, voltage calculating operation for calculating the AC voltage V1 based on the digital data D1, and output operation for outputting the AC voltage V1 calculated. The processing section 33B also functions as a judging section that converts a voltage waveform of the signal component Ss2 output from the filter 38 into digital data, detects a level of the data (an amplitude level of the signal component Ss2, or a DC voltage level (an absolute value of the DC voltage) after rectification of the signal component Ss2), and carries out a diagnosis operation for the detecting operation on the AC voltage V1 in the voltage detection device 105, by making a comparison between a detected level Va (an amplitude level, as an example) and a predetermined level Vre, specified beforehand.

In the voltage detection device 105 in this case, when the detection electrode 12 and the detection object 4 capacitively couple each other while the voltage detection device 105 is operating normally, the current signal I (concretely to describe, the reference current Is1) due to the reference signal Ss output from the reference signal output section 31 flows between the detection object 4 and the floating circuit section 2. The signal component due to the reference current Is1 is always included in the insulated detection signal S2 and the amplified detection signal S3. Therefore, as an example, if a lower limit value of the above-described level Va of the reference signal Ss included in the insulated detection signal S2 under normally operating condition is calculated theoretically or experimentally beforehand and stored as the predetermined level Vre in the storage section 34, the processing section 33B can carry out at least one of the following two judging operations (as an example, to carry out both the judging operations in the present embodiment) as the diagnosis operation, i.e., one judging operation for judging that the voltage detection device is operating normally (operation in normal condition) when the level Va in relation to the signal component Ss2 of the reference signal Ss detected is equal to or higher than the predetermined level Vre, and the other judging operation for judging that the voltage detection device may have an erroneous condition (operation in abnormal condition) when the level Va in relation to the signal component Ss2 detected is lower than the predetermined level Vre. Thus, it can be judged whether the voltage detection device 105 is operating normally (the detecting operation on the AC voltage V1 is in normal condition) or abnormally (the detecting operation on the AC voltage V1 is in abnormal condition).

Essential operation of the voltage detection device 105 is equivalent to that of the voltage detection device 101 according to the first embodiment shown in FIG. 1. In the operation, the filter 38 continuously carries out, receiving the insulated detection signal S2, extracting the signal component Ss2 of the reference signal Ss included in the insulated detection signal S2, and outputting the extracted signal component to the processing section 33B. Meanwhile, the processing section 33B carries out the diagnosis operation by using the signal component Ss2 output from the filter 38 in parallel with the storing operation and the voltage calculating operation according to the first embodiment. In the diagnosis operation, at first the processing section 33B converts a voltage waveform of the received signal component Ss2 into digital data, detects the level Va of the signal component Ss2 (the amplitude level of the signal component Ss2 in the present embodiment), and makes a comparison between the detected level Va and the predetermined level Vre read out of the storage section 34. Then, the processing section 33B judges according to the result of the comparison that the voltage detection device is operating normally (operation in normal condition) when the level Va is equal to or higher than the predetermined level Vre, whereas the voltage detection device may have an erroneous condition (operation in abnormal condition) when the level Va is lower than the predetermined level Vre. Thus, the processing section 33B stores the judgment result into the storage section 34, and completes the diagnosis operation.

Finally, the processing section 33B executes the output operation to show the RMS values, amplitudes, and other data of the AC voltage V1, which the storage section 34 stores, together with the judgment result out of the diagnosis operation at the output section 35 including the display apparatus. Thus, the detecting operation by the voltage detection device 105 completes detection of the AC voltage V1 of the detection object 4. Alternatively, it may be configured for the output operation that the RMS values, amplitudes, and other data of the AC voltage V1 are shown in the output section 35 if the processing section 33B judges the operation being in normal condition as a result of the diagnosis operation, whereas only the judgment result of the diagnosis operation is shown without the RMS values, amplitudes, and other data of the AC voltage V1 at the output section 35 if the processing section 33B judges the operation being in abnormal condition as a result of the diagnosis operation.

According to the present embodiment, the processing section 33B detects the level Va of the signal component Ss2 (the amplitude level of the signal component Ss2) of the reference signal Ss included in the insulated detection signal S2, and makes a comparison between the level Va and the predetermined level Vre to carry out the judging operation for judging whether the voltage detection device 105 is operating normally or abnormally. Therefore, according to the result of the judging operation, an operator can make a diagnosis (a judgment) on whether the voltage detection device 105 is executing the voltage detection normally or not. Thus, in accordance with the present embodiment, the operator can find whether a detected AC voltage V1 is from operation in normal condition or abnormal condition so that the reliability of the detected AC voltage V1 can be improved.

Explained in the present embodiment is an example of a configuration in which the processing section 33B makes a diagnosis for the voltage detection device 105 on the insulated detection signal S2 detected at the point “A”, which is an entrance point into the signal extracting section 32. As described above, the signal component due to the reference current Is1 is included not only in the insulated detection signal S2 but also in the amplified detection signal S3. Therefore, it may be configured that the processing section 33B makes a diagnosis on the amplified detection signal S3 detected at a point “B” that is an output point from the amplifying circuit 41. In such a configuration, the filter 38 receives the amplified detection signal S3 at the point “B” as shown with a broken line in FIG. 15, and extracts the signal component of the reference signal Ss included in the amplified detection signal S3, and then outputs it as the signal component Ss2 to the processing section 33B. The processing section 33B carries out the diagnosis operation by using the signal component Ss2 output from the filter 38, in the same manner as it makes the diagnosis for the voltage detection device 105 on the insulated detection signal S2 detected at the point “A”. Then, the processing section 33B judges that the voltage detection device is operating normally (operation in normal condition) when the level Va of the signal component Ss2 is equal to or higher than the predetermined level Vre, whereas the voltage detection device has erroneous condition (operation in abnormal condition) when the level Va is lower than the predetermined level Vre, and stores the judgment result into the storage section 34. In this case, the lower limit value of the above-described level Va of the reference signal Ss included in the amplified detection signal S3, under conditions where the voltage detection device 105 is operating normally, is calculated beforehand and used as the predetermined level Vre.

In the voltage detection device 105 operating normally, feedback control for the gain (amplification ratio) of the amplifying circuit 41 is carried out by the synchronous detection circuit 43 and the control circuit 44, for controlling in such a way that the amplitude of the anti-phase signal component (the signal component having the same frequency as the reference signal Ss) included in the amplified detection signal S3 becomes equal to the amplitude of the reference signal Ss input into the adding circuit 42 as the reference signal Sr. Thus, in the adding circuit 42, the anti-phase signal component included in the amplified detection signal S3 is canceled with the reference signal Ss. In other words, the level of the signal component (e.g., an amplitude level) of the reference signal Sr (the reference signal Ss in the present embodiment) included in the output signal So, thus the level of the detection signal Vd (a DC voltage level) output from the synchronous detection circuit 43 are consequently low. On the other hand, when the floating circuit section 2 or the feedback controls for the gain (amplification ratio) of the amplifying circuit 41 has any erroneous condition (namely, when the voltage detection device 105 is operating in abnormal condition), the level of the signal component of the reference signal Sr included in the output signal So becomes high, and thus the level of the detection signal Vd (a DC voltage level) output from the synchronous detection circuit 43 is consequently high.

It may be configured that the processing section 33B makes a diagnosis about the voltage detection device 105 on the basis of at least one of two signals, i.e., the output signal So detected at a point “C” that is an output point from the adding circuit 42, and the detection signal Vd detected at a point “D” that is an output point from the synchronous detection circuit 43. In the case of the configuration in which the diagnosis is made on the basis of the output signal So, the filter 38 receives the output signal So at the point “C” as shown with a broken line in FIG. 15, and extracts the signal component of the reference signal Ss included in the output signal So, and then outputs it as the signal component Ss2 to the processing section 33B. In the case of the diagnosis based on the output signal So detected at the point “C”, the processing section 33B judges that the voltage detection device is operating normally (operation in normal condition) when the level Va of the signal component Ss2 is equal to or lower than the predetermined level Vre, whereas the voltage detection device has erroneous condition (operation in abnormal condition) when the level Va is higher than the predetermined level Vre, contrary to the diagnosis made on the insulated detection signal S2 detected at the point “A”. Then, the processing section 33B stores the judgment result into the storage section 34. In this case, a higher limit value of the above-described level Va of the reference signal Ss included in the output signal So, under conditions where the voltage detection device 105 is operating normally, is calculated beforehand and used as the predetermined level Vre.

In the configuration in which the diagnosis is made on the basis of the detection signal Vd, the processing section 33B receives the detection signal Vd at the point “D” as shown with a broken line in FIG. 15, and in the same manner as it makes the diagnosis on the output signal So detected at the point “C”, the processing section 33B judges that the voltage detection device is operating normally (operation in normal condition) when the level Va of the detection signal Vd (This signal level is also referred to as the “level Va”) is equal to or lower than the predetermined level Vre, whereas the voltage detection device has erroneous condition (operation in abnormal condition) when the level Va is higher than the predetermined level Vre, and stores the judgment result into the storage section 34. In this case, a higher limit value of the above-described level Va of the detection signal Vd, under conditions where the voltage detection device 105 is operating normally, is calculated beforehand and used as the predetermined level Vre.

### Sixth Embodiment

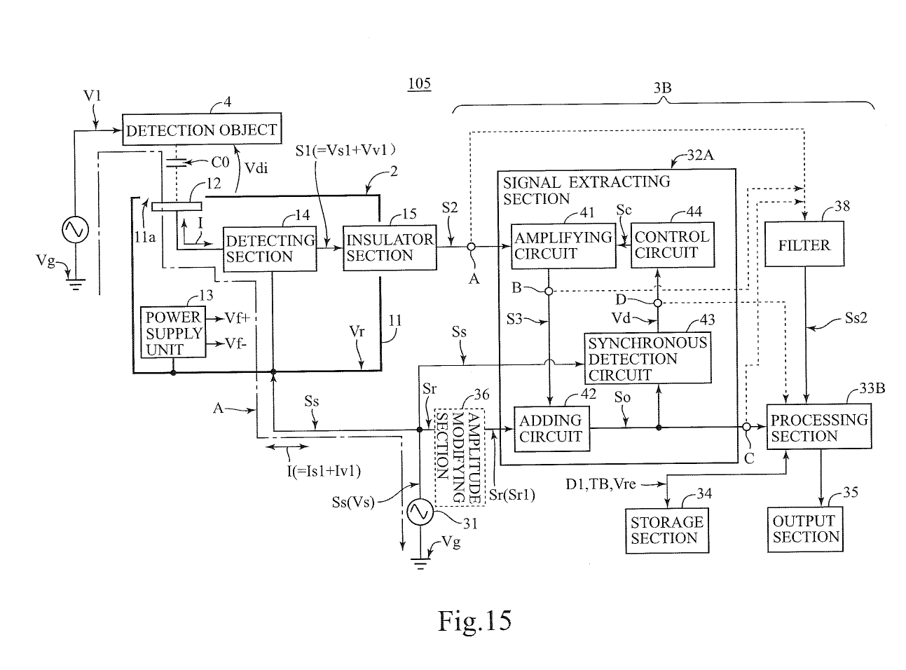

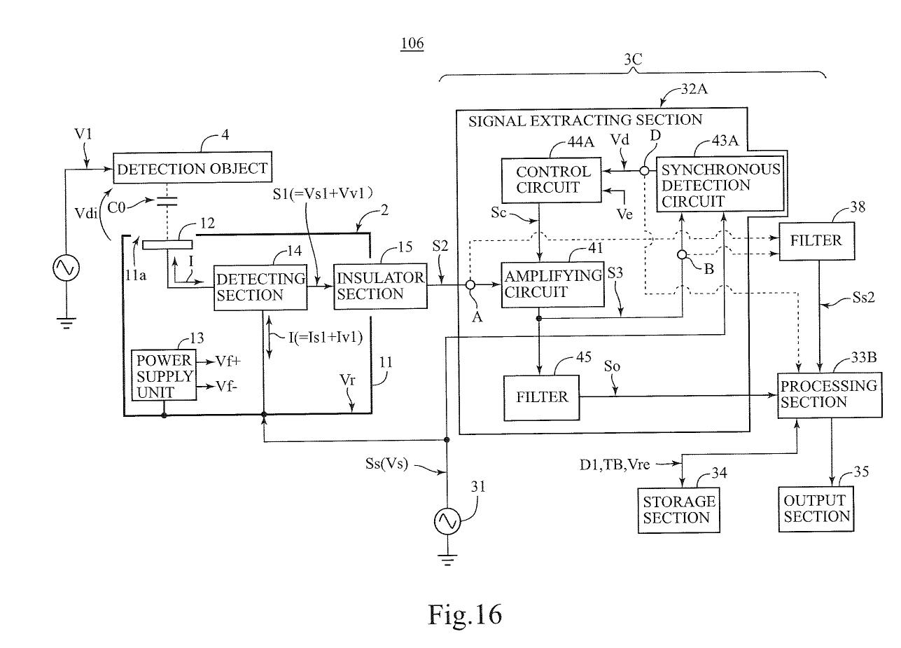

A voltage detection device 106 of a sixth embodiment according to the present invention comprised a floating circuit section 2 and a main circuit section 3C as shown in FIG. 16. The voltage detection device 106 is configured to be able to detect the AC voltage V1 arising on the detection object 4 without physical contact.

A voltage detection device 106 of a sixth embodiment in accordance with the present invention is a contact-free type voltage detection device comprising a floating circuit section 2 and a main circuit section 3C, as shown in FIG. 16. The voltage detection device 105 is configured to be able to detect the AC voltage V1 arising on the detection object 4 without physical contact. Except the signal extracting section 32A, the configuration of the main circuit section 3C is the same as the corresponding part of the voltage detection device 105 shown in FIG. 15, and the configuration of the signal extracting section 32A is the same as the corresponding parts of the voltage detection devices 103 and 104 shown in FIGS. 13 and 14. Descriptions on the configuration and operation of the signal extracting section 32A are omitted to avoid redundant explanation.

### Seventh Embodiment

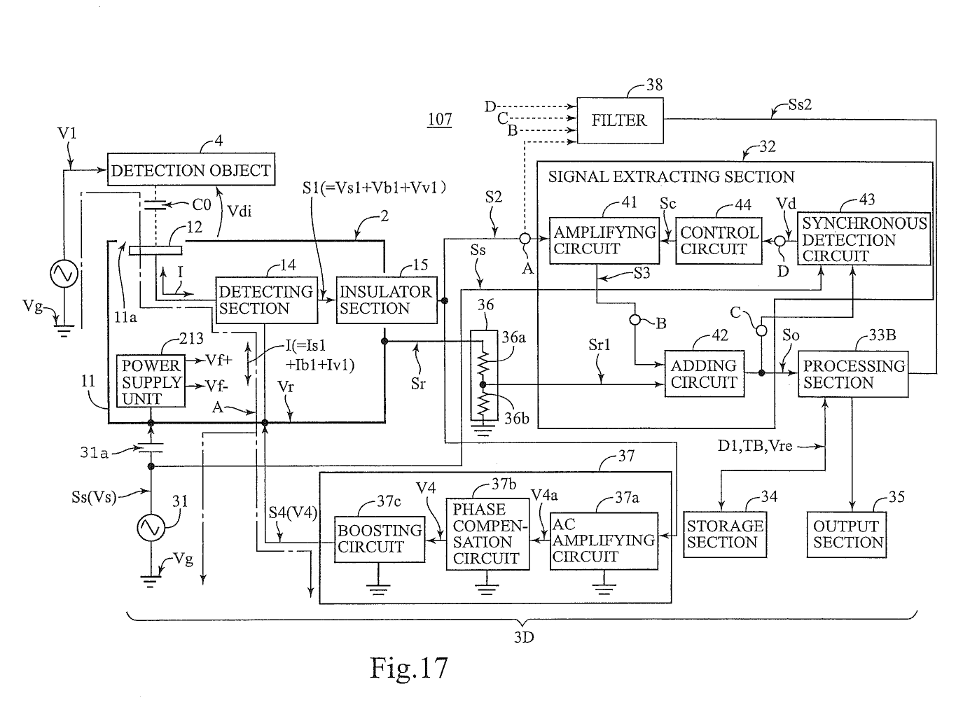

The AC voltage V1 of the detection object 4 can also be detected without physical contact by using a configuration of a voltage detection device 107 of a seventh embodiment, shown in FIG. 17, in which a voltage signal S4 is generated according to the insulated detection signal S2 so as to be output to (imposed on) the guard electrode 11, and feedback control is carried out to make a voltage V4 of the voltage signal S4 approximate to the AC voltage V1, and then the essential configuration of the voltage detection devices 101, 102, and 105 of the first, second and fifth embodiments is also used together. The processing section 33B can make a diagnosis about the voltage detection device 107 on the basis of any one of the signals detected at the points “A”, “B”, “C”, and “D”, in the same manner as done in the voltage detection device 105.

The voltage detection device 107 of the present embodiment is explained below with reference to FIG. 17, and FIGS. 5 through 22. Components of the same configuration as the voltage detection device 106 of the sixth embodiment has are provided with the same reference numerals, and any redundant explanation is omitted.

A voltage detection device 107 is a contact-free type voltage detection device comprising, as shown in FIG. 17, a floating circuit section 2 and a main circuit section 3D. The voltage detection device 107 is configured to be able to detect, by taking the ground electric potential Vg as a reference, the AC voltage V1 (the objective AC voltage) arising on the detection object 4 without physical contact.

The floating circuit section 2 comprises, as shown in FIG. 17, a guard electrode 11, a detecting electrode 12, a power supply unit 13, a detecting section 14 and an insulator section 15 and is configured in the same way as that of the voltage detection devices 105 and 106. In the floating circuit section 2, the detecting section 14 generates the detection signal S1 that changes its amplitude according to the AC potential difference (V1−Vr), in accordance with the current signal I (the detection current) flowing with a current value according to the AC potential difference (V1−Vr), and outputs the generated detection signal S1. In this case, the guard electrode 11 is applied the reference signal Ss through a condenser 301 from the reference signal output section 31 described later as well as the voltage signal S4 from a feedback controller section 37 to be described later. According to this configuration, the voltage Vr is a combined voltage of the voltage V4 (a feedback voltage) of the voltage signal S4 and the voltage Vs of the reference signal Ss. Thus, the current signal I described above includes the reference current Is1 due to the reference signal Ss, a current signal component (hereinafter, also called a “FB current component”) Ib1 due to the voltage signal S4, and the detection object current Iv1 due to the AC voltage V1 of the detection object 4, and then the detection signal S1 derived from the current signal I includes the reference voltage component Vs1 derived from the reference current Is1, a voltage signal component (hereinafter, also called a “FB voltage component”) Vb1 derived from the FB current component Ib1, and the detection object voltage component Vv1 derived from the detection object current Iv1. Since the detecting section 14 operates according to the voltage of the guard electrode 11, which changes together with the voltage Vs of the reference signal Ss and the voltage V4 of the voltage signal S4, in order to generate the detection signal S1, the reference voltage component Vs1 included in the detection signal S1 is an anti-phase signal in comparison to the reference signal Ss. Then, the FB voltage component Vb1 included in the detection signal S1 is also an anti-phase signal in comparison to the voltage signal S4.

The insulator section 15 receives the detection signal 51, and then outputs a signal as the insulated detection signal S2 electrically insulated from the detection signal S1. The floating circuit section 2, configured as described above, has a flat frequency characteristic in a wide frequency band from a low frequency area (several hertz) to a high frequency area (several hundred hertz). As described above, the floating circuit section 2 detects the current signal I (the detection current) flowing with the current value according to the AC potential difference (V1−Vr), and then generates and outputs the insulated detection signal S2 that changes its amplitude according to the AC potential difference (V1−Vr).

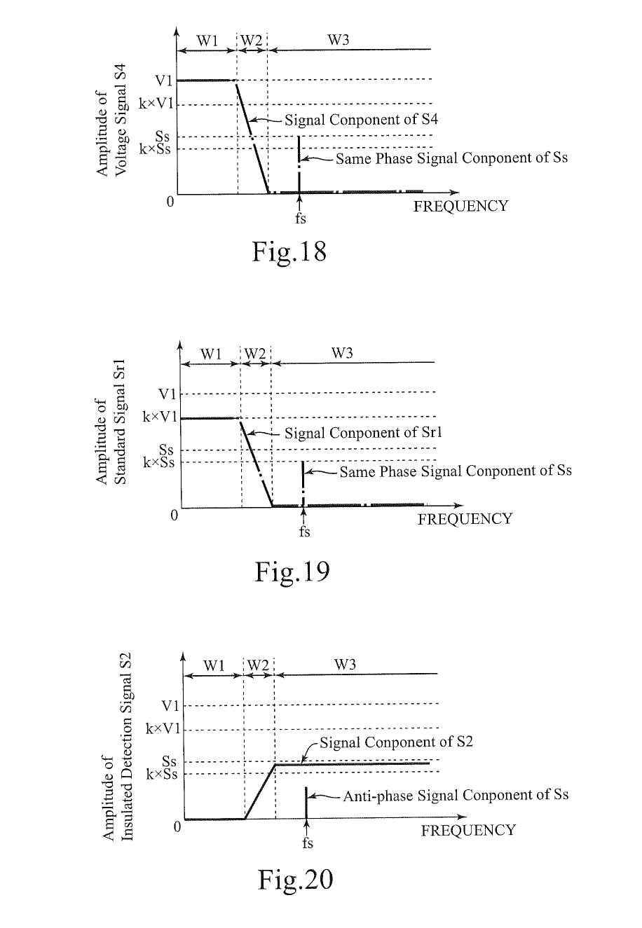

The main circuit section 3D comprises, as shown in FIG. 17, a reference signal output section 31, a signal extracting section 32, a processing section 33B, a storage section 34, an output section 35, an amplitude modifying section 36, and a feedback controller section 37. In this case, the reference signal output section 31 generates the reference signal Ss (an AC signal having a constant frequency and a constant amplitude), and outputs the signal to the guard electrode 11 via the condenser 301. As an example in the present embodiment, a frequency fs of the reference signal Ss is set within a frequency band W3 higher than frequency bands W1 and W2, in which the feedback controller section 37 can response, as described later (refer to FIG. 18). The amplitude modifying section 36 is configured by an attenuator (as an example, two resistors 36a and 36b connected in series) to receive the voltage Vr of the guard electrode 11, as a voltage signal Sr, and modify the amplitude of the signal (to multiply by k for change: wherein k is a positive real number), and then outputs the signal as the reference signal Sr1.

The signal extracting section 32 comprises, as an example, an amplifying circuit 41, an adding circuit 42, a synchronous detection circuit 43, and a control circuit 44. The signal extracting section 32 amplifies the insulated detection signal S2 with a predetermined gain to generate the amplified detection signal S3, controls the gain for amplifying the insulated detection signal S2 in order for the signal component of the reference signal Ss (hereinafter, called a “first signal component”) included in the amplified detection signal S3 and a signal component of the reference signal Ss (hereinafter, called a “second signal component”) included in the reference signal Sr1 to be cancelled by addition or subtraction of the amplified detection signal S3 and the reference signal Sr1 (by addition, as an example in the present embodiment), and then generates and outputs the output signal So including the signal component of the AC voltage V1, as described later. In this case, the first signal component of the reference signal Ss included in the amplified detection signal S3 is a signal component due to the reference voltage component Vs 1 included in the detection signal S1 according to the output of the reference signal Ss (applied on) to the guard electrode 11 (namely, a signal component having the same frequency as the reference signal Ss included in the amplified detection signal S3). On the other hand, the second signal component of the reference signal Ss included in the reference signal Sr1 is a signal component having the same frequency as the reference signal Ss included in the reference signal Sr1 according to the output of the reference signal Ss (imposed on) to the guard electrode 11.

The adding circuit 42 receives the amplified detection signal S3 and the reference signal Sr1, adds both the signals S3 and Sr1 and then outputs the addition signal obtained through the add operation as the output signal So. In this case, as described above, the detection signal S1 includes the reference voltage component Vs1 having an anti-phase in comparison to the reference signal Ss, the FB voltage component Vb1 having an anti-phase in comparison to the voltage signal S4, and the detection object voltage component Vv1 having the same phase as the AC voltage V1. Thus, the insulated detection signal S2 generated on the basis of the detection signal S1 and the amplified detection signal S3 generated by amplification of the insulated detection signal S2 also includes a signal component having an anti-phase in comparison to the reference signal Ss, a signal component having an anti-phase in comparison to the voltage signal S4, and another signal component having the same phase as the AC voltage V1. In this case, the amplified detection signal S3 is controlled in such a way that, as described later, an amplitude of the first signal component having an anti-phase (hereinafter, also called an “anti-phase signal component”) in comparison to the reference signal Ss included in the amplified detection signal S3 finally becomes the same as an amplitude of the second signal component (an amplitude resulted from multiplying the amplitude of the reference signal Ss by k: k×Ss) of the reference signal Ss included in the reference signal Sr1 output from the amplitude modifying section 36.

On the other hand, the voltage Vr of the voltage signal Sr is a combined voltage of the voltage V4 of the voltage signal S4 and the voltage Vs of the reference signal Ss, as described above. Therefore, the reference signal Sr1 generated by multiplying the amplitude of the voltage signal Sr by k includes a signal component having the same phase as the reference signal Ss (a signal generated by multiplying the amplitude of the reference signal Ss by k) and another signal component having the same phase as the voltage signal S4 (a signal generated by multiplying the amplitude of the voltage signal S4 by k).

Accordingly, the add operation of adding both the signals S3 and Sr1 by the adding circuit 42 can cancels out the anti-phase signal component (the first signal component) in comparison to the reference signal Ss included in the amplified detection signal S3 and the second signal component having the same phase (hereinafter, also called “the same phase signal component”) in comparison to the reference signal Ss included in the reference signal Sr1 each other. Therefore, the output signal So is so configured as to have signal components, in which one is anti-phase in comparison to the voltage signal S4 and the other has the same phase as the AC voltage V1, these signal components being included in the amplified detection signal S3, and another signal component, which has the same phase as the voltage signal S4, (a signal resulted from multiplying the amplitude of the voltage signal S4 by “k”) included in the reference signal Sr1.

The synchronous detection circuit 43 receives the output signal So and the reference signal Ss, generates the detection signal Vd through synchronous-detection of the output signal So with the reference signal Ss, and then outputs the detection signal Vd. The control circuit 44 generates the control signal Sc, which changes its voltage according to the polarity of the detection signal Vd entered, and outputs the signal to the amplifying circuit 41.

According to the configuration described above, feedback control for the gain (amplification ratio) of the amplifying circuit 41 is carried out in the signal extracting section 32 by the synchronous detection circuit 43 and the control circuit 44, wherein the control circuit 44 controls the gain of the amplifying circuit 41 according to the detection signal Vd so as to make the anti-phase signal component (the first signal component having the same frequency as the reference signal Ss and an anti-phase in comparison to the reference signal Ss) included in the amplified detection signal S3 have a constant amplitude (so as to have the same amplitude as that of the same phase signal component (the second signal component having the same frequency and the same phase as the reference signal Ss) included in the reference signal Sr1 input into the adding circuit 42 in the present embodiment). As a result, the amplitude of the anti-phase signal component included in the amplified detection signal S3 coincides with the amplitude of the same phase signal component of the reference signal Sr1 input into the adding circuit 42. Therefore, as described above, the adding circuit 42 generates and outputs the output signal So, which includes a signal component being anti-phase in comparison to the voltage signal S4, a signal component being the same phase as the AC voltage V1 (The above signal components being included in the amplified detection signal S3), and another signal component, which has the same phase as the voltage signal S4 (a signal component included in the reference signal Sr1).

In this case, according to the static capacitance C0 formed between the detection object 4 and the detecting electrode 12, the reference current Is1 included in the current signal I and the detection object current Iv1 fluctuate in the same ratio, and furthermore the reference voltage component Vs1 included in the detection signal S1 and the detection object voltage component Vv1 also fluctuate in the same ratio. Therefore, the anti-phase signal component (the signal component having the same frequency as the reference signal Ss) and the signal component having the same frequency as the AC voltage V1, both included in the amplified detection signal S3, also fluctuate in the same ratio. Through the feedback control in the signal extracting section 32 as described above, the amplified detection signal S3 is generated by the amplifying circuit 41 in such a way that the amplitude of the anti-phase signal component (the first signal component) included in the signal S3 coincides with the amplitude of the same phase signal component (the second signal component) included in the reference signal Sr1. Thus, in the configuration of the present embodiment, the voltage component derived from the detection object current Iv1 included in the output signal So, which is namely a signal component included in the amplified detection signal S3 (composed of one signal component being anti-phase in comparison to the voltage signal S4 and the other signal component having the same phase as the AC voltage V1), makes its amplitude correspond to a difference between the AC voltage V1 arising on the detection object 4 and the voltage signal S4, regardless of the static capacitance C0. The signal component being the same phase in comparison to the voltage signal S4 of the reference signal Sr1 included in the output signal So is a signal component generated being independent from the static capacitance C0. Therefore, the output signal So is a signal that is not affected by the static capacitance C0.

The feedback controller section (a voltage generating circuit) 37 generates the voltage signal S4 of the voltage V4 (a feedback voltage) through receiving and amplifying the insulated detection signal S2, and outputs the voltage signal S4 to (applies on) the guard electrode 11. In this case, the feedback controller section constitutes a feedback loop together with the guard electrode 11, the detecting electrode 12, the detecting section 14, and the insulator section 15 of the floating circuit section 2. The feedback controller section 37 generates the voltage signal S4 through an amplifying operation of amplifying the insulated detection signal S2 so as to reduce the potential difference Vdi between the AC voltage V1 and the voltage Vr of the guard electrode 11. As an example in the present embodiment, the feedback controller section 37 comprises an AC amplifying circuit 37a, a phase compensation circuit 37b, and a boosting circuit 37c. The AC amplifying circuit 37a receives the insulated detection signal S2 and amplifies it to generate a voltage signal V4a. In this case, the AC amplifying circuit 37a generates the voltage signal, V4a, which changes an absolute value of its voltage according to a change in an absolute value of the voltage of the insulated detection signal S2, through an amplifying operation.

The phase compensation circuit 37b receives the voltage signal V4a, adjusts the phase of the voltage signal for the purpose of stabilizing a feedback control operation (for inhibiting oscillation), and then outputs the phase-adjusted voltage signal as a voltage signal V4b. The boosting circuit 37c, which may be configured by a boosting transformer as an example, boosts the voltage signal V4b with a predetermined magnification (to increase the absolute value without changing the polarity) to generate the voltage signal S4, and outputs it to the guard electrode 11. An output impedance of the boosting circuit 37c is set with high impedance. The feedback controller section 37 configured as above generates and outputs the voltage signal S4 that changes its amplitude according to the frequency characteristic shown in FIG. 18. According to the frequency characteristic, the feedback controller section37 satisfactorily follows a signal (the AC voltage V1) having a frequency within the frequency band W1 at a low frequency side of the frequency bands W1 and W2, in which the feedback controller section 37 can response, so that the feedback controller section 37 generates and outputs the voltage signal S4 having the same voltage V4 as the AC voltage V1. For a signal (the AC voltage V1) having a frequency within the frequency band W2 at a high frequency side of the frequency bands W1 and W2, in which the feedback controller section 37 can response, the feedback controller section 37 generates and outputs the voltage signal S4 having the voltage V4 that does not reach the AC voltage V1 because of a lack of gain. For a signal having a frequency within the frequency band W3 (including the reference signal Ss) higher than the frequency band W2, the feedback controller section 37 cannot follow the signal, and then generates and outputs the voltage signal S4 having the voltage V4 of nearly 0 bolt.

The processing section 33B executes a storing operation, in which a voltage waveform (level) of the output signal So is sampled by using a sampling clock with a predetermined frequency, and converted into digital data D1, and then the data is stored in the storage section 34, a voltage calculating operation for calculating the AC voltage V1 based on the digital data D1, an output operation for outputting the AC voltage V1 calculated, and a diagnosis operation based on the level Va of the signal component Ss2 output from the filter 38. The storage section 34 stores in advance the voltage calculation table TB to be used in the voltage calculating operation in the processing section 33B as well as the predetermined level Vre to be used in the diagnosis operation.

Described below is a detecting operation for the AC voltage V1 of the detection object 4 by the voltage detection device 107.

The floating circuit section 2 (or an entire part of the voltage detection device 107) is placed in the vicinity of the detection object 4 in order for the detecting electrode 12 to face the detection object 4 without physical contact. Thus, as shown in FIG. 17, the static capacitance C0 is formed between the detecting electrode 12 and the detection object 4. Under this condition, the value of the static capacitance C0 changes in inverse proportion to a distance between the detecting electrode 12 and the detection object 4. However, after the floating circuit section 2 is once placed, the capacitance value becomes constant (without any change) as far as the temperature and other environment factors are constant. Then, since the static capacitance C0 is very small in general (for example, about several picofarads to tens of picofarads), an impedance existing between the detecting electrode 12 and the detection object 4 becomes great enough (several meg-ohms) even though the frequency of the AC voltage V1 is about several hundreds Hz. Accordingly, in the voltage detection device 107, an inexpensive device with a low withstanding input voltage may be used as the operational amplifier 21a (see FIG. 2) included in the detecting section 14, even when the AC voltage V1 of the detection object 4 and the voltage Vr of the guard electrode 11 are widely different from each other (i.e., when the potential difference Vdi is large). Then, even in this arrangement described above, destruction of the operational amplifier 21a due to the potential difference Vdi can be avoided.

Since the detecting electrode 12 and the detection object 4 are alternating-current-wise connected through the static capacitance C0, a current path “A” (a route indicated with a dashed line in FIG. 17) is formed, starting from the ground electric potential Vg, through the detection object 4, the detecting electrode 12, the detecting section 14, the guard electrode 11, the condenser 301, the reference signal output section 31, the feedback controller section 37, down to the ground electric potential Vg. Therefore, when the floating circuit section 2 and the main circuit section 3D are in operation, the current signal I, including the reference current Is1 due to the voltage Vs of the reference signal Ss, the detection object current Iv1 due to the AC voltage V1 of the detection object 4 and the FB current component Ib1 due to the voltage V4 of the voltage signal S4 output from the feedback controller section 37 to the guard electrode 11, is flowing through the current path “A”.

Accordingly, as shown in FIGS. 17 and 2, the integrating circuit 21 of the detecting section 14 in the floating circuit section 2 integrates the current signal I to generate the voltage signal S0 and the amplifying circuit 22 amplifies the voltage signal S0 and outputs the signal as the detection signal S1. The insulator section 15 receives the detection signal S1 and outputs the insulated detection signal S2 electrically insulated from the detection signal S1.

In the main circuit section 3D, the feedback controller section 37 generates the voltage signal S4 based on the insulated detection signal S2, and output it to the guard electrode 11. In this case, the feedback controller section 37 generates the voltage signal S4, which changes its amplitude according to the frequency characteristic shown in FIG. 18, namely, the voltage signal S4 having the same amplitude as the AC voltage V1 in the low frequency band W1, having an amplitude of 0 in the high frequency band W3, and having an amplitude that gradually decreases from the same amplitude level as the AC voltage V1 toward 0 according to the increase of the frequency in the intermediate frequency band W2, and outputs the voltage signal S4 to the guard electrode 11. The amplitude modifying section 36 receives the voltage Vr that appears at the guard electrode 11, as a voltage signal Sr, (the voltage Vr being a combined voltage of the voltage V4 of the voltage signal S4 and the voltage Vs of the reference signal Ss) and modifies the amplitude of the signal (multiplying by k), and then outputs it as the reference signal Sr1 having the frequency characteristic shown in FIG. 19.

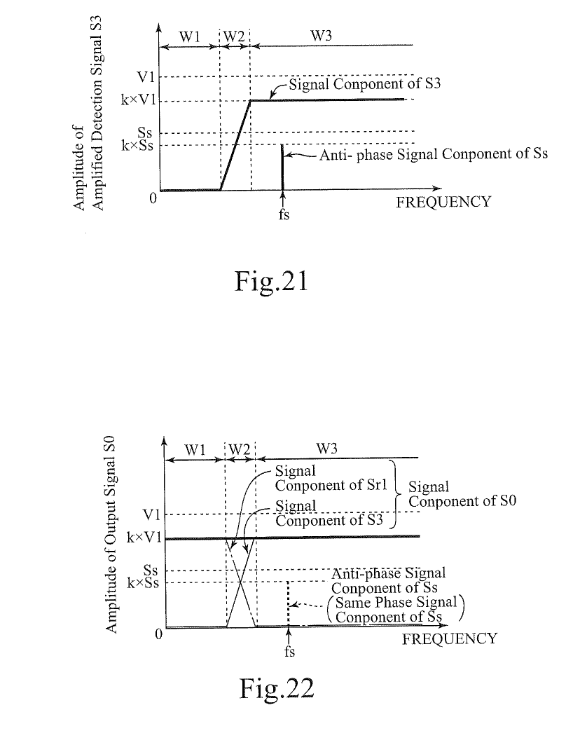

Since the feedback controller section 37 operates in such a way as described above to generate the voltage signal S4 having the frequency characteristic shown in FIG. 18, and outputs the voltage signal to the guard electrode 11, the insulated detection signal S2, which is generated by the floating circuit section 2 in the way as described above according to the potential difference Vdi between the AC voltage V1 and the voltage signal S4, becomes a signal that changes its amplitude according to a reversed frequency characteristic (See FIG. 20) opposite to the frequency characteristic on the voltage signal S4 (See FIG. 18) with respect to the signal component of the AC voltage V1 and the signal component of the voltage signal S4 (the component of the same frequency as the AC voltage V1). In other words, the floating circuit section 2 generates and outputs the insulated detection signal S2, as shown in FIG. 20, the insulated detection signal S2 having an amplitude of 0 because feedback control ise carried out to make the voltage V4 of the voltage signal S4 the same as the AC voltage V1 so that the potential difference Vdi becomes 0 in the low frequency band W1, having an amplitude proportionate to the AC voltage V1 because the voltage V4 of the voltage signal S4 is nearly 0 so that the potential difference Vdi becomes the AC voltage V1 in the high frequency band W3, and having an amplitude that gradually increases from 0 toward the amplitude of the frequency band W3 according to the increase of the frequency in the intermediate frequency band W2. As described above, feedback control for the gain (amplification ratio) of the amplifying circuit 41 is carried out in the signal extracting section 32 by the synchronous detection circuit 43 and the control circuit 44, in order for the control circuit 44 to control the gain of the amplifying circuit 41 based on the detection signal Vd so as to make the anti-phase signal component (the first signal component having the same frequency as the reference signal Ss and an anti-phase in comparison to the reference signal Ss) included in the amplified detection signal S3 have a constant amplitude (so as to have the same amplitude as that of the same phase signal component (the second signal component having the same frequency and the same phase as the reference signal Ss) included in the reference signal Sr1 input into the adding circuit 42 in the present embodiment). Thus, the amplifying circuit 41 generates and outputs the amplified detection signal S3 having the frequency characteristic shown in FIG. 21, the amplitude of the anti-phase signal component of the amplified detection signal S3 coinciding with the amplitude of the same phase signal component of the reference signal Sr1 input into the adding circuit 42. In this case, as shown in the figure, the amplitude of the amplified detection signal S3 in the frequency band W3 is k-times greater than the AC voltage V1, and then coincides with the amplitude of the reference signal Sr1 (“k”-times greater than the AC voltage V1) in the frequency band W1, as shown in FIG. 19.

Therefore, as shown in FIG. 22, by adding the amplified detection signal S3 (including a signal component with an anti-phase in comparison to voltage signal S4 and another signal component with the same phase as the AC voltage V1) having the frequency characteristic shown in FIG. 21 described above (the characteristic indicated with a solid thin line in FIG. 22) to the reference signal Sr1 (including a signal component with the same phase as the voltage signal S4) having the frequency characteristic shown in FIG. 19 described above (the characteristic indicated with a dashed line in FIG. 19), the adding circuit 42 generates and outputs the output signal So (a signal in which the amplitude is k-times greater than that of the AC voltage V1 over a wide frequency range) that has a frequency characteristic including only a signal component with the same phase as the AC voltage V1 and being a flat frequency characteristic over a wide frequency range from the low frequency band W1 to the high frequency band W3 (the characteristic indicated with a thick solid line in FIG. 22). In this case, the signal components with respect to the reference signal Ss, included in the amplified detection signal S3 and the reference signal Sr1, are canceled out since their amplitudes coincide with each other as indicated with the thick solid line in FIG. 22.

Then, the processing section 33B executes the storing operation to receive the output signal So, convert the signal into the digital data D1 and then store the data into the storage section 34. Subsequently, the processing section 33B executes the voltage calculating operation, in which the processing section 33B reads out the digital data D1 stored in the storage section 34 and retrieves the AC voltage V1 corresponding to the digital data D1 read out by reference to the voltage calculation table TB. Furthermore, the processing section 33B calculates, for example, amplitudes, RMS values, and other data of the AC voltage V1 by using the AC voltage V1 retrieved, and then stores the calculated data into the storage section 34. Furthermore, the processing section 33B also executes the diagnosis operation for the detecting operation on the AC voltage V1 in the voltage detection device 1B, and then stores a judgment result, on whether the voltage detection device 1B is operating normally or not, into the storage section 34. Finally, the processing section 33B executes the output operation to show the RMS values and amplitudes of the AC voltage V1 as well as the judgment result of the diagnosis operation and other data, which the storage section 34 stores, in the output section 35. Thus, the detecting operation by the voltage detection device 1B completes detection of the AC voltage V1 of the detection object 4.

Therefore, in accordance with the present embodiment as well, the processing section 33B detects the level Va of the signal component Ss2 of the reference signal Ss included in the insulated detection signal S2, and makes a comparison between the level Va and the predetermined level Vre to carry out the judging operation for judging whether the voltage detection device 107 is operating normally or abnormally. Then, based on the result of the judging operation, an operator can make a diagnosis (a judgment) on whether the voltage detection device 107 is executing the voltage detection normally or not. As a result, the operator can find whether a detected AC voltage V1 is from operation in normal condition or abnormal condition according to the present embodiment so that the reliability of the detected AC voltage V1 can be improved.

According to the present embodiment, an AC voltage V1 within a high frequency band, which could not be detected by detecting operation of the feedback controller section 37 alone, can be detected by using the amplified detection signal S3 that the signal extracting section 32 generates. Therefore, it becomes possible to detect any AC voltage V1 over a wide frequency range without physical contact. In, in the present embodiment as well, the output signal So can be detected as a signal that is not affected by the coupling capacitance between the detection object 4 and the detecting electrode 12 (the static capacitance C0), and therefore contact-free detection of the AC voltage V1 can be done without calculation of the static capacitance C0.

In the voltage detection device 107 of the present embodiment as well, in the same manner as done in the voltage detection device 105 of the fifth embodiment described above, the processing section may execute the diagnosis operation by using, as shown with a broken line in FIG. 17, any of the level Va of the signal component of the reference signal Ss included in the amplified detection signal S3 detected at the point “B”, the level Va of the signal component of the reference signal Ss included in the output signal So detected at the point “C”, and the level Va of the detection signal Vd detected at the point “D”, instead of the level Va of the signal component Ss2 of the reference signal Ss included in the insulated detection signal S2 detected at the point “A”. By using any of the levels Va described above, it becomes possible to make a diagnosis (a judgment) on whether the voltage detection device 107 is executing the voltage detection normally or not.

In the voltage detection devices 105 and 106 of the fifth and sixth embodiments, respectively, the detecting electrode 12, the power supply unit 13, the detecting section 14, and the insulator section 15 are accommodated within the guard electrode 11 so that the floating circuit section 2 can be configured separately from the main circuit sections 3B and 3C to increase CMRR (Common Mode Rejection Ratio) and to enable detection of the AC voltage V1 in a higher voltage range. Alternatively, if it is not required to operate the detecting section 14 under floating condition (For example, when the AC voltage V1 is relatively low, or no high CMRR is requested), the detecting section 14A (a detecting section that does not use the guard electrode 11, the power supply unit 13, and the insulator section 15) shown in FIG. 5 may be used in palace of the detecting section 14.

In the voltage detection devices 105 and 106 that use the detecting section 14A, the processing section 33B also may detect the level Va of the signal component Ss2 (an amplitude level of the signal component Ss2) of the reference signal Ss included in the detection signal S1 input instead of the insulated detection signal S2, and make a comparison between the level Va and the predetermined level Vre to carry out the judging operation for judging whether each corresponding voltage detection device 105 or 106 is operating normally or abnormally. Then, based on the result of the judging operation, an operator can make a diagnosis (a judgment) on whether the corresponding voltage detection device 105 or 106 is executing the voltage detection normally or not. Therefore, also in the voltage detection devices 105 and 106 that use the detecting section 14A, the operator can find whether a detected AC voltage V1 is from operation in normal condition or abnormal condition so that the reliability of the detected AC voltage V1 can be improved.

Also in the voltage detection device 1 using the detecting section 14A, in the same manner as in the voltage detection device 1 using the detecting section 14 described above, the processing section 33B may execute the diagnosis operation by using, as shown with a broken line in FIG. 15, any of the level Va of the signal component of the reference signal Ss included in the amplified detection signal S3 detected at the point “B”, the level Va of the signal component of the reference signal Ss included in the output signal So detected at the point “C”, and the level Va of the detection signal Vd detected at the point “D”, instead of the level Va of the signal component Ss2 of the reference signal Ss included in the detection signal S1 detected at the point “A” (a detection signal output from the detecting section 14A shown in FIG. 5, instead of the insulated detection signal S2 output from the insulator section 15 shown in FIG. 15). By using any of the levels Va described above, it becomes possible to make a diagnosis (a judgment) on whether the voltage detection device 1 is executing the voltage detection normally or not.

Also in the voltage detection device 106 using the detecting section 14A, in the same manner as in the voltage detection device 106 using the detecting section 14 described above, the processing section 33B may execute the diagnosis operation by using, as shown with a broken line in FIG. 16, either of the level Va of the signal component of the reference signal Ss included in the amplified detection signal S3 detected at the point “B” and the level Va of the detection signal Vd detected at the point “D”, instead of the level Va of the signal component Ss2 of the reference signal Ss included in the detection signal S1 detected at the point “A” (a detection signal output from the detecting section 14A shown in FIG. 5, instead of the insulated detection signal S2 output from the insulator section 15 shown in FIG. 16). By using either of the levels Va described above, it becomes possible to make a diagnosis (a judgment) on whether the voltage detection device 106 is executing the voltage detection normally or not.

What is claimed is:

1. A voltage detection device for detecting an objective AC voltage arising on a detection object comprising:
a detecting electrode placed so as to face said detection object and to be capacitively coupled with said detection object;
a reference signal output section for outputting a reference signal;
a detecting section connected to said detecting electrode and receiving the reference signal to output a detection signal changing its amplitude in accordance with both current values of a detection object current flowing according to the objective AC voltage and a reference current flowing according to the reference signal; and
a signal extracting section for extracting a signal component of the objective AC voltage from an amplified detection signal and outputting the signal component as an output signal, the amplified detection signal being obtained through controlling a gain for amplifying the detection signal so as to make a signal component of the reference signal included in the detection signal have a predetermined value.

2. The voltage detection device according to claim 1, wherein:
said signal extracting section comprises:
a control circuit for controlling the gain so as to cancel out the reference signal and a signal component of the reference signal included in the amplified detection signal each other by either addition or subtraction of the reference signal output from said reference signal output section and the amplified detection signal; and
a circuit for outputting a signal as a signal component of the objective AC voltage, the signal being generated by canceling the signal component of the reference signal included in the amplified detection signal therefrom.

3. The voltage detection device according to claim 1, wherein:
said signal extracting section comprises a control circuit for controlling the gain so as to make the predetermined value coincide with a constant value specified beforehand.

4. The voltage detection device according to claim 1 further comprising: a judging section for detecting a level of the signal component of the reference signal included in one of the detection signal and the amplified detection signal, and carrying out at least one of two judging operations; one judging operation judging the voltage detection to be in normal condition when the level detected is equal to or higher than a predetermined level, and the other judging operation judging the voltage detection to be in abnormal condition when the level detected is lower than the predetermined level.

5. The voltage detection device according to claim 1 further comprising: a power supply unit for driving said detecting section with a floating voltage using the reference signal coming from said reference signal output section as a reference voltage.

6. The voltage detection device according to claim 1, wherein:
said signal extracting section comprises:
an amplifying circuit for creating the amplified detection signal by amplifying the detection signal; and
a synchronous detection circuit for detecting a detection signal showing the amplitude of the signal component of the reference signal included in one of the amplified detection signal and the output signal, through synchronous detection using the reference signal output from the reference signal output section; and
a control circuit for controlling a gain of said amplifying circuit based on the detection signal.

7. The voltage detection device according to claim 1 further comprising: an insulator section for handing over the detection signal from said detecting section to said signal extracting section under conditions where said detecting section and said signal extracting section are electrically insulated from each other.

8. The voltage detection device according to claim 5, wherein:
said power supply unit comprises:
a first series power supply circuit for creating a first floating voltage as a certain positive voltage in comparison to the voltage of the reference signal, with reference to the positive voltage out of a positive voltage and a negative voltage supplied to said reference signal output section and said signal extracting section; and
a second series power supply circuit for creating a second floating voltage as a negative voltage, having the same absolute value as the first floating voltage, in comparison with the voltage of the reference signal, with reference to the negative voltage;
wherein said power supply unit supplies said detecting section with each of the floating voltages.

9. The voltage detection device according to claim 8, wherein:
said first series power supply circuit comprises:
a first resistor connected to the positive voltage;
a first Zener diode operating with a current supplied from said first resistor; and
a first transistor having its collector terminal connected to the positive voltage, having its base terminal receiving a Zener voltage from said first Zener diode, and creating the first floating voltage at its emitter terminal;
and wherein:
said second series power supply circuit comprises:
a second resistor connected to the negative voltage;
a second Zener diode operating with a current supplied from the second resistor; and
a second transistor having its collector terminal connected to the negative voltage, having its base terminal receiving a Zener voltage from the second Zener diode, and creating the second floating voltage at its emitter terminal.

10. The voltage detection device according to claim 2, wherein: said signal extracting section comprises one of; an adding circuit for canceling out the reference signal output from the reference signal output section and the signal component of the reference signal by the addition, and then outputting the output signal, and a subtracting circuit for canceling out the reference signal output from the reference signal output section and the signal component of the reference signal by the subtraction, and then outputting the output signal.

11. The voltage detection device according to claim 3, wherein: said signal extracting section comprises a filter for extracting a signal component of the objective AC voltage from the amplified detection signal, and outputting the signal component.

12. The voltage detection device according to claim 1 further comprising: an amplitude modifying section for changing the amplitude of the reference signal output from said reference signal output section in order to control the gain of the detection signal in said signal extracting section, and outputting the signal with the changed amplitude to said signal extracting section.

13. The voltage detection device according to claim 1 further comprising: a processing section for detecting the objective AC voltage based on the output signal.

14. The voltage detection device according to claim 13, wherein: said processing section calculates a voltage value of the objective AC voltage based on the output signal.

15. The voltage detection device according to claim 1, wherein:
said reference signal output section comprises:
a rectangular waveform generation circuit for generating a rectangular waveform; and
an integrating circuit for integrating the rectangular waveform and outputting the integration result as an integrated rectangular waveform;
wherein the integrated rectangular waveform is output to said detecting section as the reference signal; and the rectangular waveform is output to said signal extracting section as the reference signal.

16. The voltage detection device according to claim 1, wherein: said reference signal output section comprises a pseudo noise generating circuit for generating a pseudo noise, wherein the pseudo noise is output to the detecting section and the signal extracting section as the reference signal.

17. An inter-line voltage detection device comprising:
a plurality of voltage detection devices for detecting AC voltages arising on a plurality of electrical paths as a detection object; and
a calculating section for calculating difference voltages of the AC voltages detected by said plurality of voltage detection devices in order to obtain inter-line voltages between the electrical paths;
wherein said voltage detection device of claim 1 is used for configuring each of said plurality of voltage detection devices.
